(19) United States
(12) Patent Application Publication
(10) Pub. No.: US 2025/0085632 A1
(43) Pub. Date: Mar. 13, 2025

(54) UV NANOIMPRINTED LITHOGRAPHIC DEVICES MADE FROM POLYCYCLOOLEFINIC POLYMERS FOR MICROFLUIDICS

(71) Applicant: PROMERUS, LLC, AKRON, OH (US)

(72) Inventor: LARRY F. RHODES, AKRON, OH (US)

(73) Assignee: PROMERUS, LLC, AKRON, OH (US)

(21) Appl. No.: 18/830,880

(22) Filed: Sep. 11, 2024

Related U.S. Application Data
(60) Provisional application No. 63/537,737, filed on Sep. 11, 2023.

(51) Int. Cl. G03F 7/039; G03F 7/16; G03F 7/20

(52) U.S. Cl. CPC G03F 7/039; G03F 7/16; G03F 7/2002

(57) ABSTRACT

Embodiments in accordance of this invention relates generally to a composition containing polymers formed from one or more polycycloolefinic monomers at least one of which monomers containing a pendant maleimide group and a monomer which is capable of undergoing 2+2 cycloaddition reaction with the pendant group. More specifically, in an embodiment of this invention there is provided a polymer derived from one or more substituted or unsubstituted norbornene derivatives among which at least one monomer contains a substituted or unsubstituted maleimide pendant group, which polymer in combination with a monomer containing a substituted or unsubstituted maleimide forms a composition which can be used for a number of photopatternable polymeric layer when exposed to suitable actinic radiation. For example, the compositions of this invention can be used to form UV initiated nanoimprinted layers having utility in a number of applications including microfluidic devices, among others.

### CROSS REFERENCE TO RELATED APPLICATIONS

This application claims the benefit of U.S. Provisional Application No. 63/537,737, filed Sep. 11, 2023, which is incorporated herein by reference in its entirety.

### BACKGROUND OF THE INVENTION

### Field of the Invention

The present invention relates generally to a composition containing polymers formed from one or more polycycloolefinic monomers at least one of which monomers containing a pendant maleimide group and a monomer which is capable of undergoing 2+2 cycloaddition reaction with the pendant group. More specifically, in an embodiment of this invention there is provided a polymer derived from one or more substituted or unsubstituted norbornene derivatives among which at least one monomer contains a substituted or unsubstituted maleimide pendant group, which polymer in combination with a monomer containing a substituted or unsubstituted maleimide forms a composition which can be used for a number of photopatternable polymeric layer when exposed to suitable actinic radiation. For example, the compositions of this invention can be used to form UV initiated nanoimprinted layers having utility in a number of applications including microfluidic devices, among others.

### Description of the Art

Microfluidic devices are generally fabricated from hard materials, such as silicon and glass, using a combination of techniques, including photolithography and etching techniques, which is not only expensive but also not practical. Therefore, there is a need to develop soft materials which eliminate some of these disadvantageous techniques. As a result, there are efforts to employ soft materials for manufacturing devices containing valves, pumps, and mixers. Another key desirable aspect in fabricating such materials is miniaturization of the devices, from micro-scale to nano-scale. See, for example, U.S. Pat. No. 8,268,446 B2.

U.S. Pat. No. 10,975,210 B2 discloses use of silicon based polymer. However, the process described therein involves several process steps, including an adhesion to glass promoter application and an adhesion to PAZAM promoter application.

In addition, the materials that exhibit good mechanical performance, low solvent swelling are mostly sought for the fabrication of such microfluidic devices as they have to tolerate such harsh conditions while in use.

Accordingly, it is an object of this invention to provide a composition which can be used to form a variety of microfluidic devices at a micro-scale to nano-scale.

It is also an object of this invention to provide processes for the fabrication of microfluidic devices as disclosed herein.

Other objects and further scope of the applicability of the present invention will become apparent from the detailed description that follows.

### SUMMARY OF THE INVENTION

It has now been found that a composition containing a polymer derived from one or more monomers of formula (I) as described herein in combination with a monomer of formula (III), it is now possible to form a nanoimprinted layers when exposed to suitable actinic radiation. Surprisingly, the composition of this invention does not need any additional additives and are extremely effective in forming high resolution nanoimprinted images when exposed to UV radiation as described hereinbelow.

In another aspect of this invention there is also provided a process for forming nanoimprinted film comprising the composition of this invention.

### BRIEF DESCRIPTION OF THE DRAWINGS

Embodiments in accordance with the present invention are described below with reference to the following accompanying figures and/or images. Where drawings are provided, it will be drawings which are simplified portions of various embodiments of this invention and are provided for illustrative purposes only.

FIG. 1 shows atomic force micrograph (AFM) of a typical patterned surface of a conventional digital video disk (DVD).

FIG. 2 shows atomic force micrograph (AFM) of a MD700 stamp which is a replica of the patterned surface of a conventional digital video disk (DVD) shown in FIG. 1.

FIG. 3 shows an optical micrograph of a MD700 stamp.

FIG. 4 shows optical micrographs of an imprinted film embodiments of this invention (4.8 J/cm²) before and after thermal exposure (160° C. for 15 min).

FIG. 5 shows optical micrographs of an imprinted film embodiments of this invention (9.6 J/cm²) before and after thermal exposure (160° C. for 15 min).

FIG. 6 shows atomic force micrograph (AFM) of an imprinted film embodiment of this invention (9.6 J/cm²) before thermal exposure.

FIG. 7 shows atomic force micrograph (AFM) of an imprinted film embodiment of this invention (9.6 J/cm²) after thermal exposure (160° C. for 15 min).

FIG. 8 shows a graphical illustration of the change in fluorescence ratio with wavelength of a various films made from the composition embodiment of this invention.

FIG. 9 shows a graphical illustration of the change in fluorescence ratio with wavelength of a various films made from the composition embodiment of this invention which also contained Omnipol TX.

### DETAILED DESCRIPTION OF THE INVENTION

As used herein, the articles “a,” “an,” and “the” include plural referents unless otherwise expressly and unequivocally limited to one referent.

Since all numbers, values and/or expressions referring to quantities of ingredients, reaction conditions, etc., used herein and in the claims appended hereto, are subject to the various uncertainties of measurement encountered in obtaining such values, unless otherwise indicated, all are to be understood as modified in all instances by the term “about.”

Where a numerical range is disclosed herein such range is continuous, inclusive of both the minimum and maximum values of the range as well as every value between such minimum and maximum values. Still further, where a range refers to integers, every integer between the minimum and maximum values of such range is included. In addition, where multiple ranges are provided to describe a feature or characteristic, such ranges can be combined. That is to say that, unless otherwise indicated, all ranges disclosed herein are to be understood to encompass any and all sub-ranges subsumed therein. For example, a stated range of from “1 to 10” should be considered to include any and all sub-ranges between the minimum value of 1 and the maximum value of 10. Exemplary sub-ranges of the range 1 to 10 include, but are not limited to, 1 to 6.1, 3.5 to 7.8, and 5.5 to 10, etc.

As used herein, the expression “alkyl” means a saturated, straight-chain or branched-chain hydrocarbon substituent having the specified number of carbon atoms. Particular alkyl groups are methyl, ethyl, n-propyl, isopropyl, tert-butyl, and so on. Derived expressions such as “alkoxy”, “thioalkyl”, “alkoxyalkyl”, “hydroxyalkyl”, “alkylcarbonyl”, “alkoxycarbonylalkyl”, “alkoxycarbonyl”, “diphenylalkyl”, “phenylalkyl”, “phenylcarboxyalkyl” and “phenoxyalkyl” are to be construed accordingly.

As used herein, the expression “cycloalkyl” includes all of the known cyclic groups. Representative examples of “cycloalkyl” includes without any limitation cyclopropyl, cyclobutyl, cyclopentyl, cyclohexyl, cycloheptyl, cyclooctyl, and the like. Derived expressions such as “cycloalkoxy”, “cycloalkylalkyl”, “cycloalkylaryl”, “cycloalkylcarbonyl” are to be construed accordingly.

As used herein, the expression “perhaloalkyl” represents the alkyl, as defined above, wherein all of the hydrogen atoms in said alkyl group are replaced with halogen atoms selected from fluorine, chlorine, bromine or iodine. Illustrative examples include trifluoromethyl, trichloromethyl, tribromomethyl, triiodomethyl, pentafluoroethyl, pentachloroethyl, pentabromoethyl, pentaiodoethyl, and straight-chained or branched heptafluoropropyl, heptachloropropyl, heptabromopropyl, nonafluorobutyl, nonachlorobutyl, undecafluoropentyl, undecachloropentyl, tridecafluorohexyl, tridecachlorohexyl, and the like. Derived expression, “perhaloalkoxy”, is to be construed accordingly. It should further be noted that certain of the alkyl groups as described herein, such as for example, “alkyl” may partially be fluorinated, that is, only portions of the hydrogen atoms in said alkyl group are replaced with fluorine atoms and shall be construed accordingly.

As used herein the expression “acyl” shall have the same meaning as “alkanoyl”, which can also be represented structurally as “R—CO—,” where R is an “alkyl” as defined herein having the specified number of carbon atoms. Additionally, “alkylcarbonyl” shall mean same as “acyl” as defined herein. Specifically, “(C₁-C₄)acyl” shall mean formyl, acetyl or ethanoyl, propanoyl, n-butanoyl, etc. Derived expressions such as “acyloxy” and “acyloxyalkyl” are to be construed accordingly.

As used herein, the expression “aryl” means substituted or unsubstituted phenyl or naphthyl. Specific examples of substituted phenyl or naphthyl include o-, p-, m-tolyl, 1,2-, 1,3-, 1,4-xylyl, 1-methylnaphthyl, 2-methylnaphthyl, etc. “Substituted phenyl” or “substituted naphthyl” also include any of the possible substituents as further defined herein or one known in the art.

As used herein, the expression “arylalkyl” means that the aryl as defined herein is further attached to alkyl as defined herein. Representative examples include benzyl, phenylethyl, 2-phenylpropyl, 1-naphthylmethyl, 2-naphthylmethyl and the like.

As used herein, the expression “alkenyl” means a non-cyclic, straight or branched hydrocarbon chain having the specified number of carbon atoms and containing at least one carbon-carbon double bond, and includes ethenyl and straight-chained or branched propenyl, butenyl, pentenyl, hexenyl, and the like. Derived expression, “arylalkenyl” and five membered or six membered “heteroarylalkenyl” is to be construed accordingly. Illustrative examples of such derived expressions include furan-2-ethenyl, phenylethenyl, 4-methoxyphenylethenyl, and the like.

As used herein, the expression “heteroaryl” includes all of the known heteroatom containing aromatic radicals. Representative 5-membered heteroaryl radicals include furanyl, thienyl or thiophenyl, pyrrolyl, isopyrrolyl, pyrazolyl, imidazolyl, oxazolyl, thiazolyl, isothiazolyl, and the like. Representative 6-membered heteroaryl radicals include pyridinyl, pyridazinyl, pyrimidinyl, pyrazinyl, triazinyl, and the like radicals. Representative examples of bicyclic heteroaryl radicals include, benzofuranyl, benzothiophenyl, indolyl, quinolinyl, isoquinolinyl, cinnolyl, benzimidazolyl, indazolyl, pyridofuranyl, pyridothienyl, and the like radicals.

As used herein, the expression “heterocycle” includes all of the known reduced heteroatom containing cyclic radicals. Representative 5-membered heterocycle radicals include tetrahydrofuranyl, tetrahydrothiophenyl, pyrrolidinyl, 2-thiazolinyl, tetrahydrothiazolyl, tetrahydrooxazolyl, and the like. Representative 6-membered heterocycle radicals include piperidinyl, piperazinyl, morpholinyl, thiomorpholinyl, and the like. Various other heterocycle radicals include, without limitation, aziridinyl, azepanyl, diazepanyl, diazabicyclo[2.2.1]hept-2-yl, and triazocanyl, and the like.

“Halogen” or “halo” means chloro, fluoro, bromo, and iodo.

In a broad sense, the term “substituted” is contemplated to include all permissible substituents of organic compounds. In a few of the specific embodiments as disclosed herein, the term “substituted” means substituted with one or more substituents independently selected from the group consisting of (C₁₋C₆)alkyl, (C₂₋C₆)alkenyl, (C₁₋C₆)perfluoroalkyl, phenyl, hydroxy, —CO₂H, an ester, an amide, (C₁₋C₆)alkoxy, (C₁₋C₆)thioalkyl and (C₁₋C₆)perfluoroalkoxy. However, any of the other suitable substituents known to one skilled in the art can also be used in these embodiments.

It should be noted that any atom with unsatisfied valences in the text, schemes, examples and tables herein is assumed to have the appropriate number of hydrogen atom(s) to satisfy such valences.

As used herein, the expression “microfluidic device” generally refers to a device through which materials, particularly fluid borne materials, such as liquids, can be transported, in some embodiments on a micro-scale, and in some embodiments on a nano-scale. Thus, the micro fluidic devices described herein includes without any limitation both microscale features, nanoscale features, and combinations thereof.

By the term “derived” is meant that the polymeric repeating units are polymerized (formed) from, for example, polycyclic norbornene-type monomers in accordance with formulae (I) or (II) wherein the resulting polymers are formed by 2,3 enchainment of norbornene-type monomers as shown below:

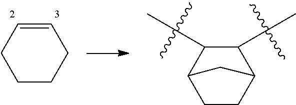

The above polymerization is also known widely as vinyl addition polymerization typically carried out in the presence of a variety of metallic compounds, generally Group VIII metallic compounds, such as for example nickel compounds or palladium compounds or platinum compounds as further described in detail below.

Thus, in accordance with the practice of this invention there is provided a composition comprising:
a) a polycycloolefinic polymer comprising at least one first repeat unit of formula (IA), said first repeat unit is derived from a monomer of formula (I):

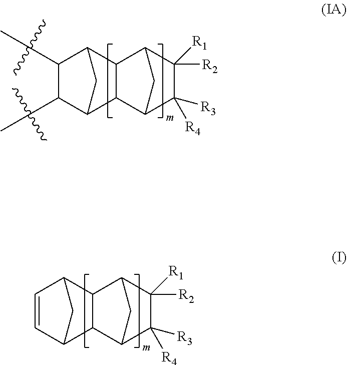

wherein:
[symbol] denotes a place of bonding with another repeat unit;
m is 0, 1 or 2;
at least one of R₁, R₂, R₃ and R₄ is selected from the group consisting of:
a radical of formula (IIA):

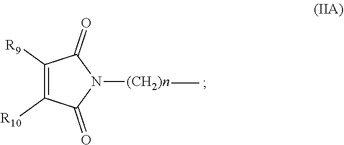

a radical of formula (IIB):

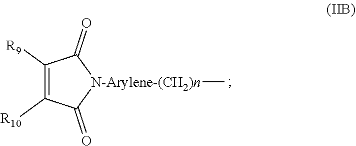

a radical of formula (IIC):

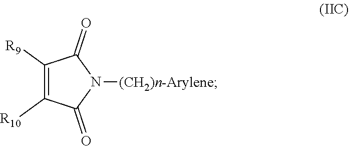

a radical of formula (IID):

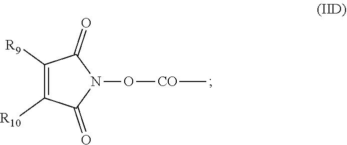

wherein:
n is an integer from 0 to 10, inclusive; and
R₉ and R₁₀ are the same or different and each independently selected from the group consisting of hydrogen, methyl, ethyl and linear or branched (C₃-C₆)alkyl; or
R₉ taken together with R₁₀ and the carbon atoms to which they are attached to form a substituted or unsubstituted (C₃-C₁₄)cyclic, (C₅-C₁₄)bicyclic or (C₅-C₁₄)tricyclic ring optionally containing one or more double bonds;
the remaining R₁, R₂, R₃ and R₄ are the same or different and each independently selected from the group consisting of hydrogen, methyl, ethyl, linear or branched (C₃-C₁₆)alkyl, (C₃-C₁₀)cycloalkyl, (C₆-C₁₂)bicycloalkyl, (C₆-C₁₂)aryl and (C₆-C₁₂)aryl(C₁-C₆)alkyl; or one of R₁ and R₂ taken together with one of R₃ and R₄ and the carbon atoms to which they are attached to form a substituted or unsubstituted (C₃-C₁₄)cyclic, (C₅-C₁₄)bicyclic or (C₅-C₁₄)tricyclic ring optionally containing one or more double bonds; and
b) a compound of formula (III):

Y—(B)_{q} (III)
wherein,
q is an integer from 1 to 6;
B is a radical of formula (IV):

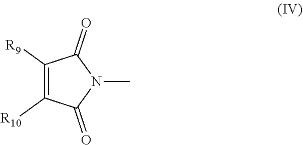

wherein R₉ and R₁₀ are as defined above;
Y is selected from the group consisting of substituted or unsubstituted methyl, ethyl, (C₃-C₁₆)alkyl, substituted or unsubstituted (C₃-C₁₆)cycloalkyl, substituted or unsubstituted (C₃-C₁₆)cycloalkyl(C₁-C₆)alkyl, substituted or unsubstituted (C₆-C₁₆)bicycloalkyl, substituted or unsubstituted (C₆-C₁₆)bicycloalkyl(C₁-C₆)alkyl, substituted or unsubstituted (C₈-C₁₆)tricycloalkyl, substituted or unsubstituted (C₈-C₁₆)tricycloalkyl(C₁-C₆)alkyl, substituted or unsubstituted (C₆-C₁₀)aryl, substituted or unsubstituted (C₆-C₁₀)aryl(C₁-C₁₆)alkyl, substituted or unsubstituted (C₅-C₁₀)heteroaryl and substituted or unsubstituted (C₆-C₁₀)heteroaryl(C₁-C₁₆)alkyl, wherein the substituents are selected from the group consisting of halogen, methoxy, ethoxy, (C₃-C₁₆)alkoxy and tris-(C₁-C₁₆)alkoxysilyl.

As noted, the polymers used in the composition of this invention can contain only one monomeric repeat unit of formula (IA). Thus, any of the homopolymers within the scope of repeat units of formula (IA) can be used in the composition of this invention. In some embodiments the composition contains a polymer, wherein:
m is 0 or 1;
at least one of R₁, R₂, R₃ and R₄ is a radical of formula (IIA):

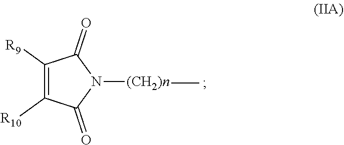

wherein:
n is an integer from 1 to 6, inclusive; and
R₉ and R₁₀ are the same or different and each independently selected from the group consisting of hydrogen, methyl and ethyl;
the remaining R₁, R₂, R₃ and R₄ are the same or different and each independently selected from the group consisting of hydrogen, methyl and ethyl.

The composition according to the present invention can also contain a polymer wherein the polymer further contains at least one second repeat unit of formula (IVA), said second repeat unit is derived from a monomer of formula (IV):

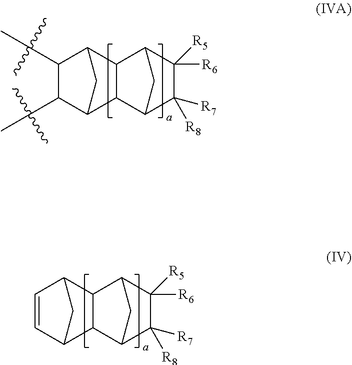

wherein:
[symbol] denotes a place of bonding with another repeat unit;
a is an integer 0, 1 or 2;
R₅, R₆, R₇ and R₈ are the same or different and each independently selected from the group consisting of hydrogen, halogen, methyl, ethyl, linear or branched (C₃-C₁₆)alkyl, (C₃-C₁₀)cycloalkyl, (C₆-C₁₂)bicycloalkyl, (C₆-C₁₂)aryl and (C₆-C₁₂)aryl(C₁-C₆)alkyl, methoxy, ethoxy, linear or branched (C₃-C₁₆)alkoxy, (C₃-C₁₂)cycloalkoxy, (C₆-C₁₂)bicycloalkoxy, (C₇-C₁₄)tricycloalkoxy, (C₆-C₁₀)aryloxy and (C₆-C₁₀)aryl(C₁-C₆)alkoxy; or one of R₅ and R₆ taken together with one of R₇ and R₈ and the carbon atoms to which they are attached to form a substituted or unsubstituted (C₅-C₁₄)cyclic, (C₅-C₁₄)bicyclic or (C₅-C₁₄)tricyclic ring optionally containing one or more double bonds.

Again, any of the polymers containing one or more repeat units of formula (IA) and one or more repeat units of formula (IVA), if employed, can be used in the composition of this invention. In some embodiments the composition contains a polymer wherein:
a is 0 or 1;
R₅, R₆, R₇ and R₈ are the same or different and each independently selected from the group consisting of hydrogen, chlorine, fluorine, methyl, ethyl, propyl, butyl, hexyl, decyl, cyclohexyl, phenyl, phenethyl and norbornyl.

The polymer as described herein can be prepared by any of the known vinyl addition polymerization in the art. For example, U.S. Pat. No. 9,175,123 B2 describes a number of such polymers, pertinent portions of which are incorporated herein by reference. It has been observed that the polymer employed in the composition of this invention can be a homopolymer containing only the repeat units of formula (IA) as described herein. However, in some embodiments there may be a need to employ a copolymer containing at least one second repeat unit of formula (IVA). Any of the desired amounts of at least one monomer of formula (I) and one monomer of formula (IV) can be employed to prepare a copolymer for this purpose. Accordingly, in some embodiments the composition according to this invention employs a polymer that contains said first repeat unit of formula (IA) and said second repeat unit of formula (IVA) in a molar ratio of from 99:1 to 50:50. In some other embodiments the molar ratio of first repeat unit of formula (IA) and the second repeat unit of formula (IVA) can be 95:5, 90:10, 80:20, 70:30, 60:40, and so on.

It should further be noted that two distinctive monomers of formula (I) can also be employed to form a polymer which is suitable in the composition of this invention. In some embodiments two distinctive monomers of formula (I) is employed with one or more distinct monomers for formula (IV). Accordingly, all such possible combination of monomers are within the scope of this invention.

Again, any of the monomers of formula (I) within the scope of this invention can be employed to form the polymer that can be employed in the composition of this invention. Accordingly, the composition according to this invention contains a polymer, wherein said first repeat unit of formula (IA) is derived from a monomer of formula (I) selected from the group consisting of:

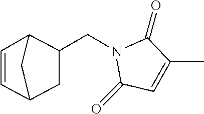

1-(bicyclo[2.2.1]hept-5-en-2-ylmethyl)-1H-pyrrole-2,5-dione (MIMeNB);

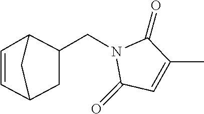 [SMILES: CC1=CC(=O)N(CC2CC3C=CC2C3)C1=O]

1-(bicyclo[2.2.1]hept-5-en-2-ylmethyl)-3-methyl-1H-pyrrole-2,5-dione (MMIMeNB);

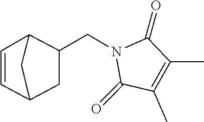 [SMILES: CC1=C(C)C(=O)N(CC2CC3C=CC2C3)C1=O]

1-(bicyclo[2.2.1]hept-5-en-2-ylmethyl)-3,4-dimethyl-1H-pyrrole-2,5-dione (DMMIMeNB);

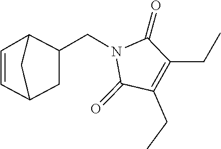 [SMILES: CCC1=C(CC)C(=O)N(CC2CC3C=CC2C3)C1=O]

1-(bicyclo[2.2.1]hept-5-en-2-ylmethyl)-3,4-diethyl-1H-pyrrole-2,5-dione (DEMIMeNB);

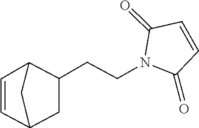 [SMILES: O=C1C=CC(=O)N1CCC1CC2C=CC1C2]

1-(2-(bicyclo[2.2.1]hept-5-en-2-yl)ethyl)-1H-pyrrole-2,5-dione (MIEtNB);

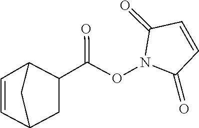 [SMILES: O=C(ON1C(=O)C=CC1=O)C1CC2C=CC1C2]

2,5-dioxo-2,5-dihydro-1H-pyrrol-1-yl bicyclo[2.2.1]hept-5-ene-2-carboxylate (5-norbornene-2-maleimide ester);

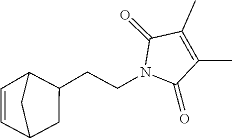 [SMILES: CC1=C(C)C(=O)N(CCC2CC3C=CC2C3)C1=O]

1-(2-(bicyclo[2.2.1]hept-5-en-2-yl)ethyl)-3,4-dimethyl-1H-pyrrole-2,5-dione (DMMIEtNB);

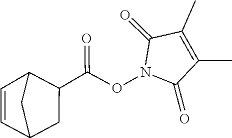 [SMILES: CC1=C(C)C(=O)N(OC(=O)C2CC3C=CC2C3)C1=O]

3,4-dimethyl-2,5-dioxo-2,5-dihydro-1H-pyrrol-1-yl bicyclo[2.2.1]hept-5-ene-2-carboxylate;

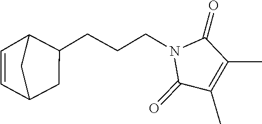 [SMILES: CC1=C(C)C(=O)N(CCCC2CC3C=CC2C3)C1=O]

1-(3-(bicyclo[2.2.1]hept-5-en-2-yl)propyl)-3,4-dimethyl-1H-pyrrole-2,5-dione (DMMIPrNB);

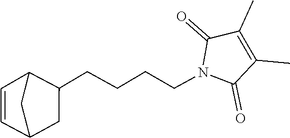 [SMILES: CC1=C(C)C(=O)N(CCCCC2CC3C=CC2C3)C1=O]

1-(4-(bicyclo[2.2.1]hept-5-en-2-yl)butyl)-3,4-dimethyl-1H-pyrrole-2,5-dione (DMMIBuNB);

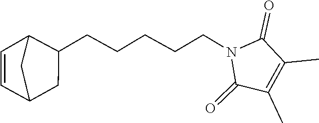 [SMILES: CC1=C(C)C(=O)N(CCCCCC2CC3C=CC2C3)C1=O]

1-(5-(bicyclo[2.2.1]hept-5-en-2-yl)pentyl)-3,4-dimethyl-1H-pyrrole-2,5-dione (DMMIPeNB);

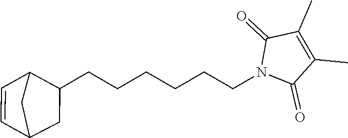 [SMILES: CC1=C(C)C(=O)N(CCCCCCC2CC3C=CC2C3)C1=O]

1-(6-(bicyclo[2.2.1]hept-5-en-2-yl)hexyl)-3,4-dimethyl-1H-pyrrole-2,5-dione (DMMIHxNB);

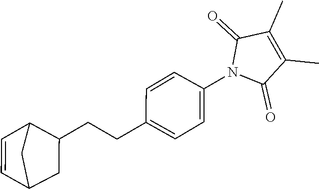 [SMILES: CC1=C(C)C(=O)N(c2ccc(CCC3CC4C=CC3C4)cc2)C1=O]

1-(4-(2-(bicyclo[2.2.1]hept-5-en-2-yl)ethyl)phenyl)-3,4-dimethyl-1H-pyrrole-2,5-dione (DMMIPhEtNB);

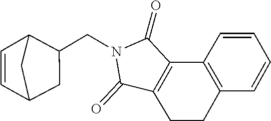 [SMILES: O=C1C2=C(C(=O)N1CC1CC3C=CC1C3)c1ccccc1CC2]

2-(bicyclo[2.2.1]hept-5-en-2-ylmethyl)-4,5-dihydro-1H-benzo[e]isoindole-1,3(2H)-dione (DHNMIMeNB); and

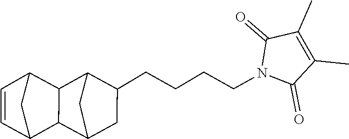 [SMILES: CC1=C(C)C(=O)N(CCCCC2CC3CC2C2C4C=CC(C4)C32)C1=O]

3,4-dimethyl-1-(4-(1,2,3,4,4a,5,8,8a-octahydro-1,4:5,8-dimethanonaphthalen-2-yl)butyl)-1H-pyrrole-2,5-dione (DMMIBuTD).

Similarly, any of the monomers of formula (IV) within the scope of this invention can be employed to form the copolymer that can be employed in the composition of this invention. Accordingly, the composition according to this invention contains a copolymer, wherein the second repeat unit of formula (IVA) is derived from a monomer of formula (IV) selected from the group consisting of:

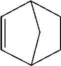

bicyclo[2.2.1]hept-2-ene (norbornene or NB);

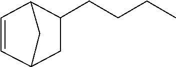

5-butylbicyclo[2.2.1]hept-2-ene (BuNB);

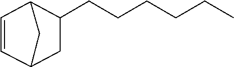

5-hexylbicyclo[2.2.1]hept-2-ene (HexNB);

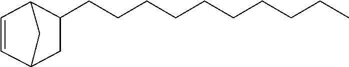 [SMILES: CCCCCCCCCCC1CC2C=CC1C2]

5-decylbicyclo[2.2.1]hept-2-ene (DecNB);

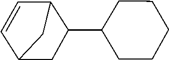 [SMILES: C1=CC2CC1CC2C1CCCCC1]

5-cyclohexylbicyclo[2.2.1]hept-2-ene (CyHexaneNB);

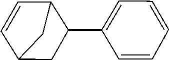 [SMILES: C1=CC2CC1CC2c1ccccc1]

5-phenylbicyclo[2.2.1]hept-2-ene (PhNB);

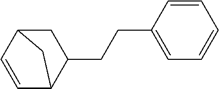 [SMILES: C1=CC2CC1CC2CCc1ccccc1]

5-phenethylbicyclo[2.2.1]hept-2-ene (PENB);

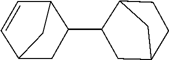 [SMILES: C1=CC2CC1CC2C1CC2CCC1C2]

2,2′-bi(bicyclo[2.2.1]heptan-5-ene) (NBANB);

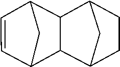 [SMILES: C1=CC2CC1C1C3CCC(C3)C21]

1,2,3,4,4a,5,8,8a-octahydro-1,4:5,8-dimethanonaphthalene (TD); and

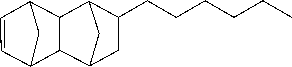 [SMILES: CCCCCCC1CC2CC1C1C3C=CC(C3)C21]

2-hexyl-1,2,3,4,4a,5,8,8a-octahydro-1,4:5,8-dimethanonaphthalene (HexTD).

The polymers employed in the composition according to this invention generally exhibit a weight average molecular weight (M_{w}) of at least about 80,000. In another embodiment, the polymer used in this invention has a M_{w} of at least about 90,000, 100,000, 150,000 or 200,000. In another embodiment, the polymer used in this invention has a M_{w} of higher than 200,000, higher than 300,000 and can be higher than 500,000 in some other embodiments. The weight average molecular weight (M_{w}) of the polymer can be determined by any of the known techniques, such as for example, by gel permeation chromatography (GPC) equipped with suitable detector and calibration standards, such as differential refractive index detector calibrated with narrow-distribution polystyrene standards or polybutadiene (PBD) standards. The polymers of this invention typically exhibit polydispersity index (PDI) of about 2, which is a ratio of weight average molecular weight (M_{w}) to number average molecular weight (Mₙ).

As noted, the composition of this invention also contains a compound of formula (III). Any of the compounds within the scope of formula (III) can be employed in the composition of this invention. Such compounds may include all possible geometric or positional or regio isomers. As used herein geometric isomers mean two or more compounds which differ from each other in the arrangement of groups with respect to a double bond, ring, or other rigid structure. Similarly, positional isomers refers to constitutional isomers with the identical carbon skeleton and functional groups but differ in where the functional groups are located on or in the carbon chain. Finally, regio isomers are similar to positional isomers but may include spatial orientation, for example, axial vs. equatorial orientation. All such combinations are within the scope of this invention. In some embodiments the compounds of formula (III) is having:
q is 1, 2 or 3;
n is an integer from 1 to 6, inclusive; and
R₉ and R₁₀ are the same or different and each independently selected from the group consisting of hydrogen, methyl and ethyl; and
Y is selected from the group consisting of triethoxysilylpropyl, butyl, hexyl, cyclohexyl, cyclohexylmethyl, norbornylmethyl and tetracyclodecylmethyl.

Again, any of the compounds within the scope of formula (III) can be used in the composition of this invention. The compounds of formula (III) are either known in the art or can be prepared by any of the methods known in the art. One such method includes for example condensation of a suitably substituted precursor amine with suitably substituted maleic anhydride to form a desirable maleimides of formula (III) as described herein. It should further be noted that a few of the compounds of formula (III) as described herein are novel and can be readily prepared by a method as described herein or by any of the other methods known in the art. Non-limiting examples of such compounds of formula (III) may be enumerated as follows:

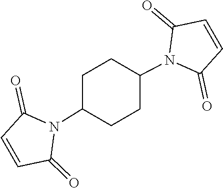 [SMILES: O=C1C=CC(=O)N1C1CCC(N2C(=O)C=CC2=O)CC1]

1,1′-(cyclohexane-1,4-diyl)bis(1H-pyrrole-2,5-dione) (1,4-CyHx(MI)₂);

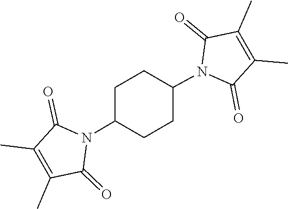

1,1′-(cyclohexane-1,4-diyl)bis(3,4-dimethyl-1H-pyrrole-2,5-dione) (CyHx(DMMI)₂);

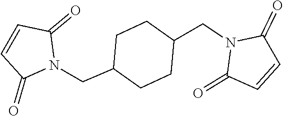 [SMILES: O=C1C=CC(=O)N1CC1CCC(CN2C(=O)C=CC2=O)CC1]

1,1′-(cyclohexane-1,4-diylbis(methylene))bis(1H-pyrrole-2,5-dione) (1,4-CyHxCH₂-MI₂);

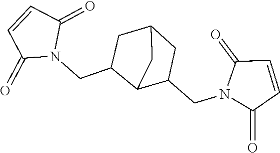 [SMILES: O=C1C=CC(=O)N1CC1CC2CC(CN3C(=O)C=CC3=O)C1C2]

1,1′-(bicyclo[2.2.1]heptane-2,6-diylbis(methylene))bis(1H-pyrrole-2,5-dione) (2,6-NB(CH₂-MI)₂);

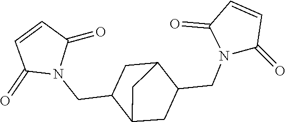 [SMILES: O=C1C=CC(=O)N1CC1CC2CC1CC2CN1C(=O)C=CC1=O]

1,1′-(bicyclo[2.2.1]heptane-2,5-diylbis(methylene))bis(1H-pyrrole-2,5-dione) (2,5-NB(CH₂-MI)₂);

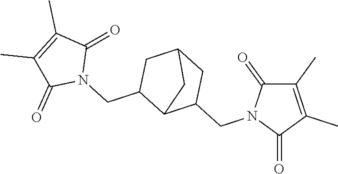

1,1′-(bicyclo[2.2.1]heptane-2,6-diylbis(methylene))bis(3,4-dimethyl-1H-pyrrole-2,5-dione) (2,6-NB(CH₂-DMMI)₂);

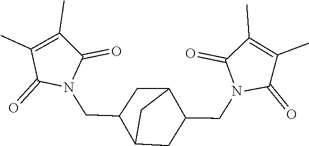

1,1′-(bicyclo[2.2.1]heptane-2,5-diylbis(methylene))bis(3,4-dimethyl-1H-pyrrole-2,5-dione) (2,5-NB(CH₂-DMMI)₂);

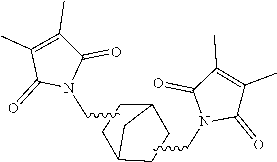

an isomeric mixture of (bicyclo[2.2.1]heptane-diylbis(methylene))bis(3,4-dimethyl-1H-pyrrole-2,5-dione) (NB(CH₂-DMMI)₂);

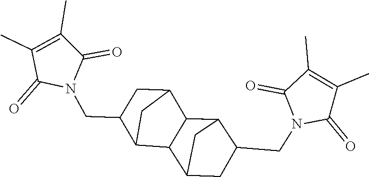

1,1′-((decahydro-1,4:5,8-dimethanonaphthalene-2,6-diyl)bis(methylene))bis(3,4-dimethyl-1H-pyrrole-2,5-dione) (2,6-TD(CH₂-DMMI)₂);

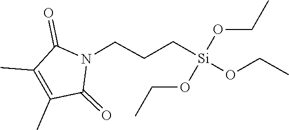 [SMILES: CCO[Si](CCCN1C(=O)C(C)=C(C)C1=O)(OCC)OCC]

3,4-dimethyl-1-[3-(triethoxysilyl)propyl]-1H-pyrrole-2,5-dione (DMMI-Pr-TEOS);

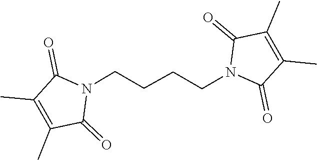

1,1′-(butane-1,4-diyl)bis(3,4-dimethyl-1H-pyrrole-2,5-dione) (DMMI-Bu-DMMI); and

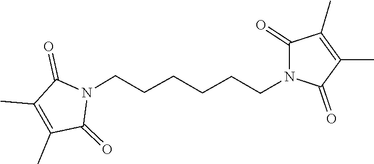

1,1′-(hexane-1,6-diyl)bis(3,4-dimethyl-1H-pyrrole-2,5-dione) (DMMI-Hx-DMMI).

It should further be noted that more than one compound of formula (III) can be used in the composition of this invention. Accordingly, in some embodiments two compounds of formula (III) are employed in the composition of this invention. Again, as noted all positional isomers are included in the composition of this invention. Accordingly, in some embodiments the composition contains all possible isomeric mixture of one or more compounds of formula (III).

As noted, any of the polymers containing at least one repeat unit of formula (IA) and optionally a repeat unit of formula (IVA) as described herein in combination with at least one compound of formula (III) can be employed in the composition of this invention. Generally, the composition of this invention is dissolved in a suitable solvent to form a homogeneous solution. Generally, such solvents to form the composition of this invention include for example, aromatic solvents such as toluene, mesitylene, xylenes, hydrocarbon solvents such as decalin, cyclohexane and methyl cyclohexane, ether solvent such as tetrahydrofuran (THF), ester solvent such as ethyl acetate, ether-ester solvent such as propylene glycol methyl ether acetate (PGMEA), ketone solvents such as methyl ethyl ketone (MEK) or methyl n-amyl ketone (MAK), and a mixture in any combination thereof. Any other solvent which would dissolve both the polymer containing a repeat unit of formula (IA) and a compound of formula (III) can also be used to form the composition of this invention.

It is contemplated that by employing a mixture of a polymer containing at least one repeat unit of formula (IA), optionally in combination with a repeat unit of formula (IVA), and a compound of formula (III) it is now possible to form a composition which when exposed to suitable radiation through a mask undergoes a 2+2 cycloaddition reaction to form a patterned layer. More specifically, the envisaged 2+2 cycloaddition reaction is shown in Scheme I using a homopolymer containing a repeat unit of formula (IA) formed from a respective norbornene monomer substituted with maleimide, which when subjected to suitable actinic radiation as described herein with any of the compound of formula (III) forms a cycloaddition adduct as shown in Scheme I. Thus, the composition of this invention can be used in a variety of applications, including to form a patterned layer containing micro-patterns to nano-patterns or a combination thereof.

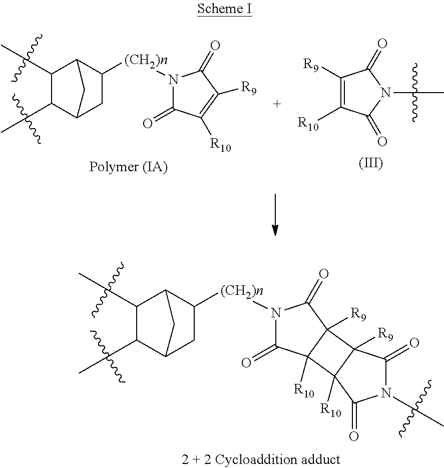

Any amounts of the polymer containing the first repeat units of formula (IA), optionally containing the second repeat units of formula (IVA), as described herein can be used in combination with at least one compound of formula (III) to form the composition of this invention. In some embodiments the weight ratio of the polymer and the compound of formula (III) employed to form the composition of this invention can be from 10:90 to 90:10. In some other embodiments the weight ratio of polymer to compound of formula (III) can be 20:80, 30:70, 40:60, 50:50, 60:40, 70:30, 80:20, and so on. However, it should be noted any other amounts of polymer and the compound of formula (III) can be employed to form the composition depending upon the intended use. All such combinations of amounts are within the scope of this invention. Generally, equal parts by weight of the polymer and compound of formula (III) (i.e., 50:50 weight ratio) are used to form the composition of this invention.

Advantageously, the composition of this invention does not require any other additives to form the patterned layer as described herein. This aspect is especially advantageous over any of the methods available in the art. For example, U.S. Pat. No. 10,975,210 B2 describes a method for preparing a functionalized surface and the use thereof in DNA sequencing and other diagnostic applications. The method described therein is quite complicated. More specifically, a surface of a patterned substrate is first silanized using (2-(bicyclo[2.2.1]hept-5-en-2-yl)ethyl)trimethoxysilane (2-(trimethoxysilyl)ethyl-5-norbornene). The silanization is generally carried out using the method of chemical vapor deposition (CVD). Then PAZAM is covalently linked on to the silanized layer. Each of these steps further involve complicated subs-steps as described therein. Thus, the prior art method not only involves a number of undesirable steps but also not practical for fabricating a variety of devices and is expensive.

Surprisingly, the composition of this invention provides extremely inexpensive practical way to fabricate a variety of devices as contemplated herein as it eliminates most of the aforementioned prior art steps thus providing several process advantages over the prior art methods for fabrication of many devices especially microfluidics commonly used in the industry. Optionally a monomer of formula (I) is used in the composition as an additional ingredient to anchor various biological molecules such as oligonucleotides, proteins, and the like by covalently bond the olefinic group of the monomer of formula (I) with the biological molecules by a variety of reactions known in the art, such as for example, click reaction as further described in detail below.

Accordingly, various compositions can now be formed by practice of this invention for forming patterned layers having utility in a number of applications. Non-limiting examples of composition according to this invention is selected from the group consisting of:
a solution containing a homopolymer of 1-(4-(bicyclo[2.2.1]hept-5-en-2-yl)butyl)-3,4-dimethyl-1H-pyrrole-2,5-dione (DMMIBuNB) and 3,4-dimethyl-1-[3-(triethoxysilyl)propyl]-1H-pyrrole-2,5-dione (DMMI-Pr-TEOS);
a solution containing a homopolymer of 1-(4-(bicyclo[2.2.1]hept-5-en-2-yl)butyl)-3,4-dimethyl-1H-pyrrole-2,5-dione (DMMIBuNB) and an isomeric mixture of (bicyclo[2.2.1]heptane-diylbis(methylene))bis(3,4-dimethyl-1H-pyrrole-2,5-dione) (NB(CH₂-DMMI)₂); and
a solution containing a copolymer of 1-(4-(bicyclo[2.2.1]hept-5-en-2-yl)butyl)-3,4-dimethyl-1H-pyrrole-2,5-dione (DMMIBuNB) and 2-hexyl-1,2,3,4,4a,5,8,8a-octahydro-1,4:5,8-dimethanonaphthalene (HexTD) and 3,4-dimethyl-1-[3-(triethoxysilyl)propyl]-1H-pyrrole-2,5-dione (DMMI-Pr-TEOS).

In general, as noted, the composition of this invention are used as such without any need for other additives. However, the compositions in accordance with the present invention may further contain optional additives as is customary and may be useful for the purpose of improving properties of both the composition and the resulting object made therefrom. Such optional additives for example may include photoinitiators, anti-oxidants, synergists, and the like. Any of the photoinitiators known in the art that would bring about the intended benefit can be used in the compositions of this invention. Non-limiting examples of such photoinitiators include di-ester of carboxymethoxy thioxanthone and polytetramethyleneglycol 250, commercially available as OMNIPOL TX® from IGM Resins; and 2,2-dimethoxy-1,2-diphenylethan-1-one, commercially available as IRGACURE® 651 from BASF. Any of the anti-oxidants as needed that would bring about the intended benefit can be used in the compositions of this invention. Non-limiting examples of such antioxidants include pentaerythritol tetrakis(3-(3,5-di-tert-butyl-4-hydroxyphenyl)propionate) (IRGANOX™ 1010 from BASF), 3,5-bis(1,1-dimethylethyl)-4-hydroxy-octadecyl ester benzenepropainoic acid (IRGANOX™ 1076 from BASF) and thiodiethylenebis[3-(3,5-di-tert.-butyl-4-hydroxy-phenyl)propionate](IRGANOX™ 1035 from BASF). Non-limiting examples of such synergists, if needed, include certain of the secondary antioxidants which may provide additional benefits such as for example prevention of autoxidation and thereby degradation of the composition of this invention and extending the performance of primary antioxidants, among other benefits. Examples of such synergists include, tris(2,4-ditert-butylphenyl)phosphite, commercially available as IRGAFOS 168 from BASF, various diamine synergists such as for example, N,N′-di-2-naphthyl-1,4-phenylenediamine, among others.

Accordingly, there is further provided a patterned layer formed from the composition of this invention. In some embodiments the composition used to form the patterned layer contains a polymer containing at least one repeat unit of formula (IA) as described herein and at least one compound of formula (III). In some other embodiments the composition used to form the patterned layer contains a polymer containing at least one repeat unit of formula (IA) and at least one repeat unit of formula (IVA) as described herein and at least one compound of formula (III).

The patterned layer can have various patterns ranging from microscale to nanoscale dimensions of varied complexity. The term “microscale” as used herein means a dimension ranging in the order of 0.1 micrometers (m) to 1000 m. The term “nanoscale” as used herein means a dimension ranging in the order of 1 nanometer (nm) to 100 nm. In some embodiments the patterned layers feature a plurality of shapes, which include but not limited to channels, fluid reservoirs, reaction chambers, mixing chambers, separation regions, as is customarily used in such devices as microfluidics. Accordingly, in some embodiments the channels include at least one cross-sectional dimension which ranges from about 0.1 m to about 500 m. The term “channel” as used herein means a recess or cavity formed on a substrate or a device as described herein which is formed by imparting a pattern from a patterned substrate such as a mask as further described in detail below.

Accordingly, there is further provided a microfluidic device comprising a plurality of patterned layers formed from the composition of this invention. In some embodiments the microfluidic device is formed from a composition comprising a polymer containing at least one repeat unit of formula (IA) as described herein and at least one compound of formula (III). In some other embodiments the microfluidic device is formed from a composition comprising a polymer containing at least one repeat unit of formula (IA) and at least one repeat unit of formula (IVA) as described herein and at least one compound of formula (III).

In a further aspect of this invention there is provided a kit for forming a plurality of patterned film layers. There is dispensed in this kit a composition of this invention. Accordingly, in some embodiments there is provided a kit in which there is dispensed a polycycloolefinic polymer comprising at least one first repeat unit of formula (IA) as described herein and at least one compound of formula (III) as described herein. In some embodiments the kit of this invention contains a polymer comprising one first repeat unit of formula (IA) and one second repeat unit of formula (IVA) as described herein and at least one compound of formula (III) as described herein. Any of the specific polymers containing at least one repeat unit of formula (IA), optionally one or more repeat units of formula (IVA) as described herein along with any of the compounds of formula (III) can be used in the kit of this invention.

In yet another aspect of this invention there is further provided a method of forming a patterned layers for the fabrication of a variety of devices including microfluidics comprising:
a) coating a suitable substrate with the composition as described herein or pouring the composition onto a suitable substrate to form a film;
b) placing a patterned soft stamp on the coated substrate;
c) placing a glass slide on top of the soft stamp to form a stack;
d) exposing the stack to a suitable actinic radiation;
e) removing the glass slide and the stamp to obtain the patterned substrate.

Again, any of the composition as described herein can be used in the method of this invention, which includes a polymer containing only the repeat unit of formula (IA) or the polymer containing at least one repeat unit of formula (IA) in combination with one or more repeat units of formula (IVA). All of the polymers derived from various monomers of formula (I) optionally in combination with one or more monomers of formula (IVA) can be used for this purpose. Similarly, any of the compounds of formula (III) as described herein can be used in this aspect of the invention.

The coating of the desired substrate to form a film with the composition of this invention can be performed by any of the coating procedures as described herein and/or known to one skilled in the art, such as by spin coating. Other suitable coating methods include without any limitation spraying, doctor blading, meniscus coating, ink jet coating and slot coating. The composition can also be poured onto a substrate to form a film. Suitable substrates include any appropriate substrate as is, or may be used for fabricating microfluidic devices, for example, a semiconductor substrate, a ceramic substrate, a glass substrate.

Next, the coated substrate can be heated to facilitate the removal of solvent if necessary, for example to a temperature from 50° C. to 100° C. for about 1 to 30 minutes, although other appropriate temperatures and times can be used. In some embodiments the substrate is simply air dried at room temperature—around 20° C. to 30° C. for about 1 to 10 minutes to remove any residual solvent.

Next, a patterned stamp is placed on the substrate. As would be recognized by one of ordinary skill in the art, patterned stamp, often referred to in the art as “soft stamp” can be made by any of the photo patternable polymers. One such example being a stamp made from perfluoropolyethers (PFPEs), various such polymers are known in the art. Examples of such PFPEs include without any limitation, poly(hexafluoropropene oxide) (HFPO), available from DuPont as KRYTOX® or from Solvay as FLUOROLINK® MD700, among others. The soft stamp features patterns as desired in the final device that is being fabricated. In some embodiments the thickness of the patterned layers in the stamp can range from 10 nm to 1000 nm. In some other embodiments the thickness of the patterned layers in the stamp can range from 10 nm to 500 nm. In yet some other embodiments the thickness of the patterned layers in the stamp can range from 50 nm to 100 nm.

Next, the stamp is covered by a suitable material such as a glass slide. Any of the other protective materials can be used for this purpose. Then the whole stack is exposed to suitable actinic radiation. Generally such appropriate actinic radiation is having a wavelength of from about 200 nm to 700 nm. In some embodiments, the actinic radiation employed is ultraviolet (UV) radiation, more specifically in the wavelength of from about 250 nm to 450 nm. In some embodiments the UV radiation has a wavelength of about 365 nm. In some embodiments the period of time the stack exposed to the UV radiation ranges from about one second to about 300 seconds. In some other embodiments the period of time the stack exposed to the UV radiation ranges from about six seconds to about 100 seconds. Any of the dosage of UV radiation can be used which brings about the intended benefit. Accordingly, in some embodiments the exposure dose can range from about 1 to 20 J/cm² at 365 nm UV radiation. In some other embodiments the exposure dose can range from about 2 to 10 J/cm² at 365 nm UV radiation.

The patterned layers thus formed can be examined by optical or atomic force microscopy. In general, the patterns thus formed are replicative of the patterns in the stamp.

Finally, by optional use of sufficient amounts of a monomer of formula (I) in the composition of this invention it is now possible to anchor a variety of biological molecules. Accordingly, in some embodiments the composition of this invention comprises a polymer containing at least one repeat unit of formula (IA) optionally in combination with one or more repeat units of formula (IVA), at least one compound of formula (III) and one or more monomer of formula (I) as descried herein. The patterned surface formed from such a composition will feature unreacted monomer of formula (I) which can be used to covalently bond any of the biological molecules commonly used in a microfluidic devices as is known in the art.

This invention is further illustrated by the following examples which are provided for illustration purposes and in no way limit the scope of the present invention.

### Examples (General)

The following abbreviations have been used hereinbefore and hereafter in describing some of the compounds, instruments and/or methods employed to illustrate certain of the embodiments of this invention:

DMMIBuNB—1-(4-(bicyclo[2.2.1]hept-5-en-2-yl)butyl)-3,4-dimethyl-1H-pyrrole-2,5-dione; poly or pDMMIBuNB—homopolymer of DMMIBuNB; DMMI-Pr-TEOS—3,4-dimethyl-1-[3-(triethoxysilyl)propyl]-1H-pyrrole-2,5-dione; MD700—Fluorolink© MD700 perfluoropolyether from Solvay; Irgacure 651—2,2-dimethoxy-1,2-diphenylethan-1-one (from BASF); Omnipol TX—di-ester of carboxymethoxy thioxanthone and polytetramethyleneglycol 250 (from IGM Resins); PGMEA—propylene glycol methyl ether acetate; PTFE—polytetrafluoroethylene; phr—parts per hundred parts resin, DVD—digital video disk; AFM—atomic force microscopy; PEB—post exposure bake; FT—film thickness; GPC—gel permeation chromatography; M_{w}—weight average molecular weight; Mₙ—number average molecular weight; PDI—polydispersity index.

The homopolymer of DMMIBuNB employed in the following examples was prepared in accordance with the procedures set forth in U.S. Pat. No. 9,175,123, Example B64, pertinent portions of which are incorporated herein by reference. The polymer thus formed was characterized by GPC: M_{w}=119,000; PDI=2.1. Similarly, DMMI-Pr-TEOS was prepared following the procedures as set forth in Example AD1 of U.S. Pat. No. 9,175,123, pertinent portions of which are incorporated herein by reference.

### Example 1

### Soft Stamp Fabrication

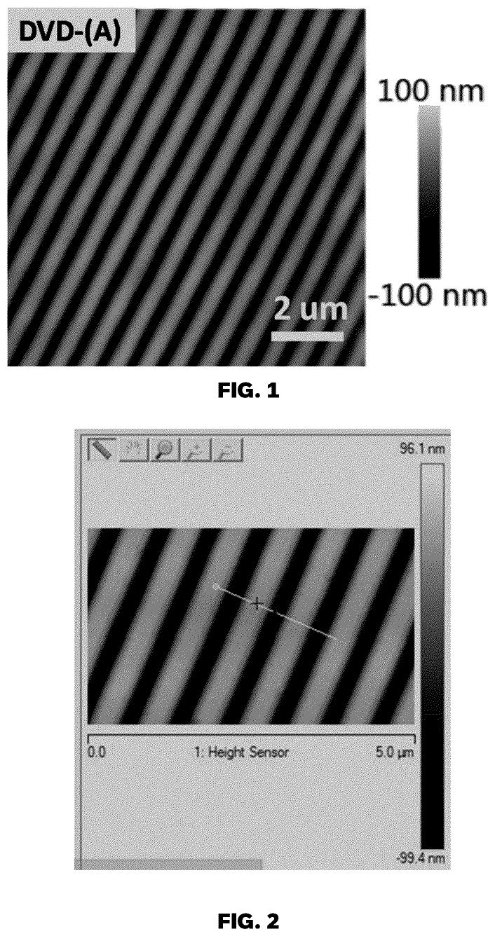

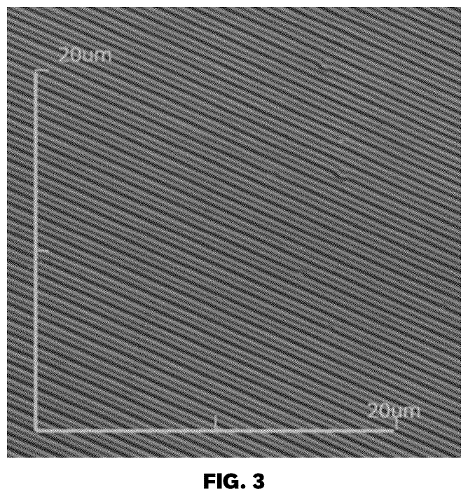

A DVD (Sony Electronics Inc.) was separated using a razor blade to expose the channel patterned surface. After cleaning with methanol, the rigid polycarbonate channel pattern was exposed and ready to use. Irgacure 651 (1%) was dissolved in MD700 and then poured onto the channeled surface of the polycarbonate. The MD700 formulation on the polycarbonate substrate was exposed in a UV curing unit (Electro-lite Corporation, ELC-4001, dose of 2000 mJ/cm² at 365 nm). The cured MD700 film was peeled off from polycarbonate substrate. The MD700 film was cut to 1 cm² square pieces and was used as the soft stamp for embossing the polymers below. The DVD after separation and cleaning and the cured MD700 stamp were characterized by optical and atomic force microscopy (AFM). FIG. 1 shows the AFM image of the DVD surface. FIG. 2 shows the AFM image of the MD700 soft stamp. It is apparent from AFM images, the MD700 soft stamp seems to replicate the DVD mold. FIG. 3 shows the optical micrograph of MD700 soft stamp which again demonstrates that uniform patterns of the DVD are replicated in the MD700 soft stamp.

### Example 2

### UV-NIL Imprinting

This Example 2 illustrates how to form a UV-NIL imprinted replicas using the composition embodiments of this invention.

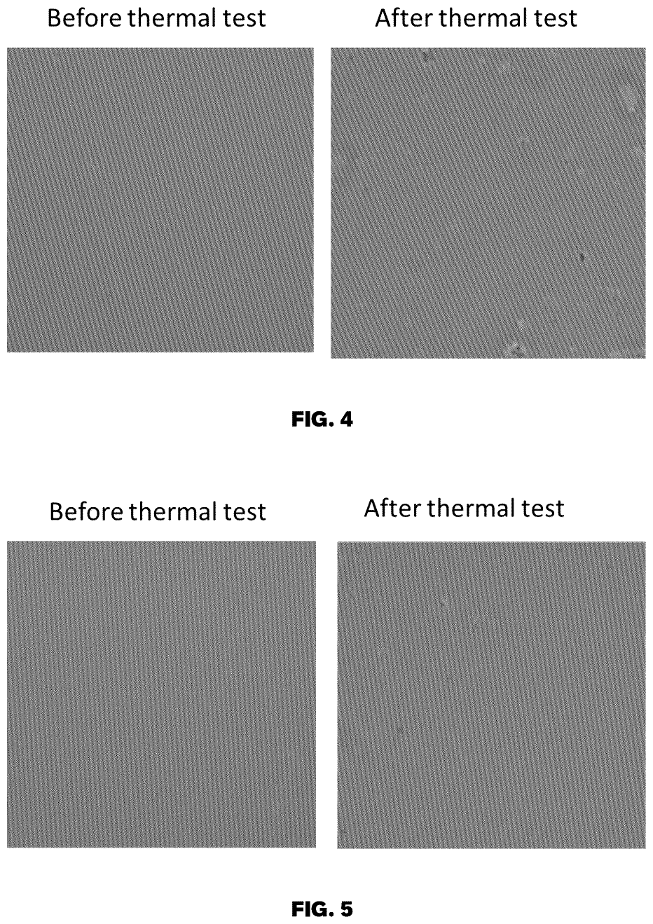

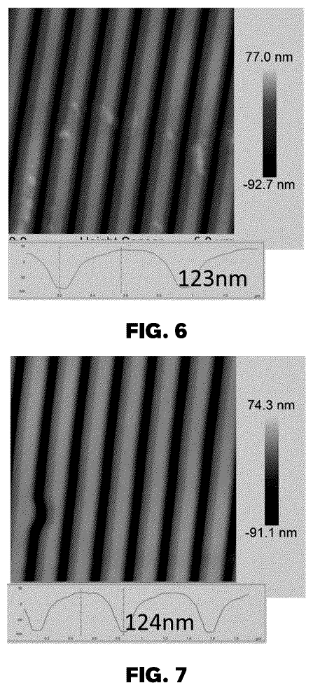

The homopolymer of DMMIBuNB (0.5 g) (prepared in accordance with the procedures set forth in U.S. Pat. No. 9,175,123, Example B64, as mentioned above) was dissolved in PGMEA (9 g) along with DMMI-Pr-TEOS (0.5 g) (prepared in accordance with the procedures set forth in U.S. Pat. No. 9,175,123, Example AD1, as mentioned above). The composition thus formed was spin coated onto a glass slide using a 500 rpm for 10 sec followed by a 2000 rpm for 30 sec protocol. The MD700 stamp was placed onto the coated glass slide. Another glass slide was placed on top and the whole stack was clamped together using a paper binder clip. The entire stack was exposed using an Electro-lite UV exposure unit (ELC-4001) at dose of 4.8 J/cm² (365 nm). The experiment was repeated but at an exposure dose of 9.6 J/cm² (365 nm). The stacks were dissembled and the imprinted polymer films were characterized by optical or optical and AFM microscopy. The imprinted films were then heated to 160° C. for 15 min and then examined by optical or optical and AFM microscopy. FIG. 4 shows optical micrographs of imprinted films (4.8 J/cm²) before and after thermal exposure (160° C. for 15 min). FIG. 5 shows optical micrographs of imprinted films (9.6 J/cm²) before and after thermal exposure (160° C. for 15 min). A comparison of the images before and after thermal treatment shows that the images did not change. FIGS. 6 and 7 show AFM images of imprinted film (9.6 J/cm²) before and after thermal exposure, respectively.

### Example 3

### Fluorescence Tests

A composition was formed containing the homopolymer of DMMIBuNB (prepared in accordance with the procedures set forth in U.S. Pat. No. 9,175,123, Example B64, as mentioned above) and DMMI-Pr-TEOS (prepared in accordance with the procedures set forth in U.S. Pat. No. 9,175,123, Example AD1, as mentioned above) at a 50/50 weight ratio in PGMEA (10%) (1.5 g of polymer, 1.5 g of DMMI-Pr-TEOS, 27 g of PGMEA). Thermal oxide silicon wafers were spin coated (500 rpm for 40 sec) with the above composition after the composition was filtered through a 0.2 micron PTFE filter. According to the protocol listed in Table 1, the films were then either not exposed, exposed with a dose of 4.8 J/cm² or 9.6 J/cm² (365 nm) using an Electro-lite UV exposure unit (ELC-4001) and were either not post-exposure baked (PEB) or baked at 120° C. for 2 min or 160° C. for 15 min. The film thickness of the samples was determined by profilometry.

TABLE 1

| Film No. | Exposure (365 nm) | PEB | FT (profilometry) |
|---|---|---|---|
| 1 | none | 160° C., 15 min | 0.402 |
| 2 | 4.8 J/cm² | 160° C., 15 min | 0.584 |
| 3 | 4.8 J/cm² | none | 0.642 |
| 4 | 9.6 J/cm² | none | 0.652 |
| 5 | 9.6 J/cm² | 160° C., 15 min | 0.545 |
| 6 | none | 120° C., 2 min | 0.391 |

The experiments above were repeated except that the composition included 0.08 phr of Omnipol TX. The results are summarized in Table 2.

TABLE 2

| Film No. | Exposure (365 nm) | PEB | FT (profilometry) |
|---|---|---|---|
| 1 | none | 160° C., 15 min | 0.404 μm |
| 2 | 4.8 J/cm² | 160° C., 15 min | 0.599 μm |
| 3 | 4.8 J/cm² | none | 0.671 μm |
| 4 | 9.6 J/cm² | none | 0.652 μm |
| 5 | 9.6 J/cm² | 160° C., 15 min | 0.574 μm |
| 6 | none | 120° C., 2 min | 0.411 μm |

The fluorescence of the processed films was determined using a Horiba FluoroMax spectrofluorometer, using the parameters listed in Table 3.

TABLE 3

| Instrument | Horiba FluoroMax spectrofluorometer | |
|---|---|---|
| Source | 150 W CW Ozone-free xenon arc lamp | |
| Sample Holder | 1933 Solid-Sample Holder | |
| Detector | Photomultiplier R928P, | |
| | spectral coverage 200 nm-870 nm | |
| Excitation | 532 | nm |
| Wavelength | | |
| Excitation Slit Width | 5 | nm |
| Emission Wavelength | 590-700 nm (30°) and 550-625 nm (60°) | |
| Emission Slit Width | 1 | nm |

| | |
|---|---|
| Detection | Corrected Signal/Corrected Reference (S1c/R1c) |
| Scan temperature | Room temperature |

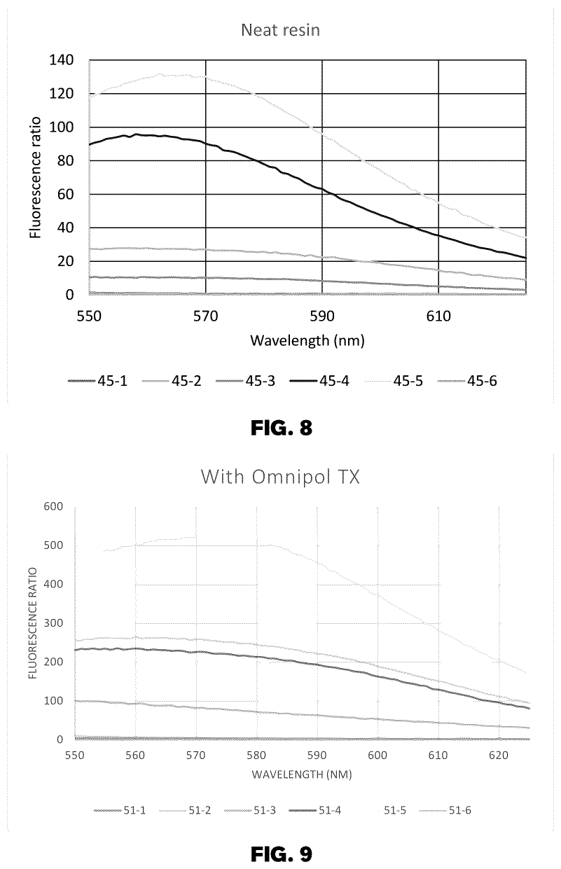

The data from this measurement are reported as a fluorescence ratio obtained by dividing the observed fluorescence in the sample by the fluorescence of the substrate (4 inch thermal oxide silicon wafer, see Mair, et al. Lab Chip, 2006, 6, 1346). FIGS. 8 and 9 show respectively the graphical relationship of the fluorescence ratio measured over various wavelength of the films formed from the composition containing the neat resin as well as the composition containing the resin and Omnipol TX.

The compositions with Omnipol TX for the most part exhibited higher fluorescence all other processing conditions being equal. From this data it appears that the best combination of exposure and post exposure heating would be 4.8 J/cm² following by 120° C. for 2 min without Omnipol TX. This should give a fluorescence ratio of no more than 10.

Although the invention has been illustrated by certain of the preceding examples, it is not to be construed as being limited thereby; but rather, the invention encompasses the generic area as hereinbefore disclosed. Various modifications and embodiments can be made without departing from the spirit and scope thereof.

What is claimed is:

1. A composition comprising:
a) a polycycloolefinic polymer comprising at least one first repeat unit of formula (IA),
said first repeat unit is derived from a monomer of formula (I): 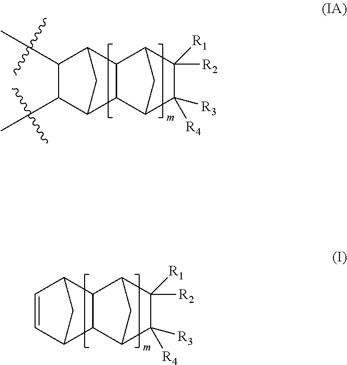
wherein: [symbol]
denotes a place of bonding with another repeat unit;
m is 0, 1 or 2;
at least one of R₁, R₂, R₃ and R₄ is selected from the group consisting of:
a radical of formula (IIA): 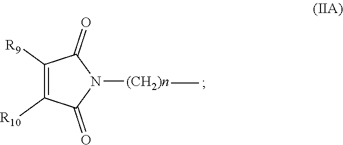
a radical of formula (IIB): 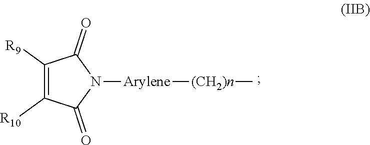
a radical of formula (IIC): 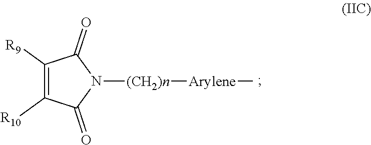
and
a radical of formula (IID): 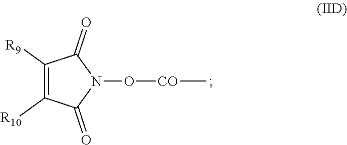
wherein:
n is an integer from 0 to 10, inclusive; and
R₉ and R₁₀ are the same or different and each independently selected from the group consisting of hydrogen, methyl, ethyl and linear or branched (C₃-C₆)alkyl; or
R₉ taken together with R₁₀ and the carbon atoms to which they are attached to form a substituted or unsubstituted (C₃-C₁₄)cyclic, (C₅-C₁₄)bicyclic or (C₅-C₁₄)tricyclic ring optionally containing one or more double bonds;
the remaining R₁, R₂, R₃ and R₄ are the same or different and each independently selected from the group consisting of hydrogen, methyl, ethyl, linear or branched (C₃-C₁₆)alkyl, (C₃-C₁₀)cycloalkyl, (C₆-C₁₂)bicycloalkyl, (C₆-C₁₂)aryl and (C₆-C₁₂)aryl(C₁-C₆)alkyl; or
one of R₁ and R₂ taken together with one of R₃ and R₄ and the carbon atoms to which they are attached to form a substituted or unsubstituted (C₃-C₁₄)cyclic, (C₅-C₁₄)bicyclic or (C₅-C₁₄)tricyclic ring optionally containing one or more double bonds; and
b) a compound of formula (III):
Y—(B)_{q} (III)
wherein,
q is an integer from 1 to 6;
B is a radical of formula (IV): 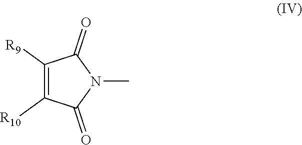
wherein R₉ and R₁₀ are as defined above;
Y is selected from the group consisting of substituted or unsubstituted methyl, ethyl, (C₃-C₁₆)alkyl, substituted or unsubstituted (C₃-C₁₆)cycloalkyl, substituted or unsubstituted (C₃-C₁₆)cycloalkyl(C₁-C₆)alkyl, substituted or unsubstituted (C₆-C₁₆)bicycloalkyl, substituted or unsubstituted (C₆-C₁₆)bicycloalkyl(C₁-C₆)alkyl, substituted or unsubstituted (C₅-C₁₆)tricycloalkyl, substituted or unsubstituted (C₅-C₁₆)tricycloalkyl(C₁-C₆)alkyl, substituted or unsubstituted (C₆-C₁₀)aryl, substituted or unsubstituted (C₆-C₁₀)aryl(C₁-C₁₆)alkyl, substituted or unsubstituted (C₅-C₁₀)heteroaryl and substituted or unsubstituted (C₆-C₁₀)heteroaryl(C₁-C₁₆)alkyl, wherein the substituents are selected from the group consisting of halogen, methoxy, ethoxy, (C₃-C₁₆)alkoxy and tris-(C₁-C₁₆)alkoxysilyl.

2. The composition according to claim 1, wherein the polymer further comprising at least one second repeat unit of formula (IVA), said second repeat unit is derived from a monomer of formula (IV): 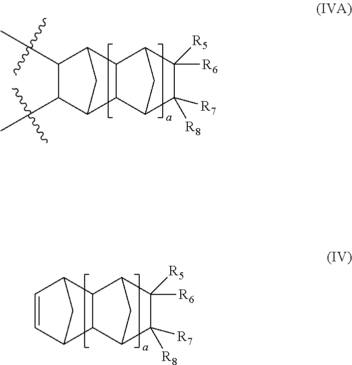
wherein: [symbol]
denotes a place of bonding with another repeat unit;
a is an integer 0, 1 or 2;
R₅, R₆, R₇ and R₈ are the same or different and each independently selected from the group consisting of hydrogen, halogen, methyl, ethyl, linear or branched (C₃-C₁₆)alkyl, (C₃-C₁₀)cycloalkyl, (C₆-C₁₂)bicycloalkyl, (C₆-C₁₂)aryl and (C₆-C₁₂)aryl(C₁-C₆)alkyl, methoxy, ethoxy, linear or branched (C₃-C₁₆)alkoxy, (C₃-C₁₂)cycloalkoxy, (C₆-C₁₂)bicycloalkoxy, (C₇-C₁₄)tricycloalkoxy, (C₆-C₁₀)aryloxy and (C₆-C₁₀)aryl(C₁-C₆)alkoxy; or
one of R₅ and R₆ taken together with one of R₇ and R₈ and the carbon atoms to which they are attached to form a substituted or unsubstituted (C₅-C₁₄)cyclic, (C₅-C₁₄)bicyclic or (C₅-C₁₄)tricyclic ring optionally containing one or more double bonds.

3. The composition according to claim 2, wherein said polymer contains said first repeat unit of formula (IA) and said second repeat unit of formula (IVA) in a molar ratio of from 99:1 to 50:50.

4. The composition according to claim 1, wherein said first repeat unit of formula (IA) is derived from a monomer of formula (I) selected from the group consisting of: 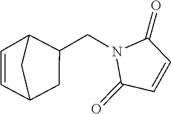
1-(bicyclo[2.2.1]hept-5-en-2-ylmethyl)-1H-pyrrole-2,5-dione (MIMeNB); 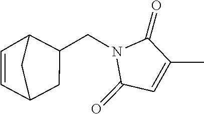 [SMILES: CC1=CC(=O)N(CC2CC3C=CC2C3)C1=O]
1-(bicyclo[2.2.1]hept-5-en-2-ylmethyl)-3-methyl-1H-pyrrole-2,5-dione (MMIMeNB); 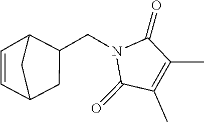 [SMILES: CC1=C(C)C(=O)N(CC2CC3C=CC2C3)C1=O]
1-(bicyclo[2.2.1]hept-5-en-2-ylmethyl)-3,4-dimethyl-1H-pyrrole-2,5-dione (DMMIMeNB); 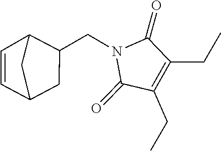 [SMILES: CCC1=C(CC)C(=O)N(CC2CC3C=CC2C3)C1=O]
1-(bicyclo[2.2.1]hept-5-en-2-ylmethyl)-3,4-diethyl-1H-pyrrole-2,5-dione (DEMIMeNB); 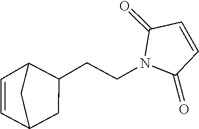 [SMILES: O=C1C=CC(=O)N1CCC1CC2C=CC1C2]
1-(2-(bicyclo[2.2.1]hept-5-en-2-yl)ethyl)-1H-pyrrole-2,5-dione (MIEtNB); 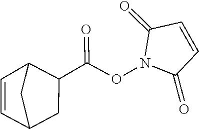 [SMILES: O=C(ON1C(=O)C=CC1=O)C1CC2C=CC1C2]
2,5-dioxo-2,5-dihydro-1H-pyrrol-1-yl bicyclo[2.2.1]hept-5-ene-2-carboxylate (5-norbornene-2-maleimide ester); 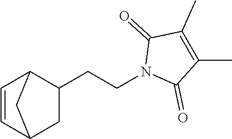 [SMILES: CC1=C(C)C(=O)N(CCC2CC3C=CC2C3)C1=O]
1-(2-(bicyclo[2.2.1]hept-5-en-2-yl)ethyl)-3,4-dimethyl-1H-pyrrole-2,5-dione (DMMIEtNB); 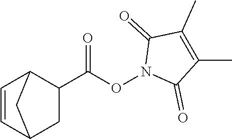 [SMILES: CC1=C(C)C(=O)N(OC(=O)C2CC3C=CC2C3)C1=O]
3,4-dimethyl-2,5-dioxo-2,5-dihydro-1H-pyrrol-1-yl bicyclo[2.2.1]hept-5-ene-2-carboxylate; 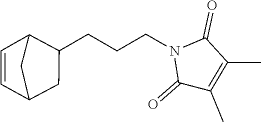 [SMILES: CC1=C(C)C(=O)N(CCCC2CC3C=CC2C3)C1=O]
1-(3-(bicyclo[2.2.1]hept-5-en-2-yl)propyl)-3,4-dimethyl-1H-pyrrole-2,5-dione (DMMIPrNB); 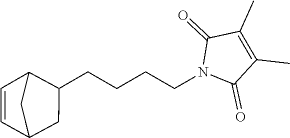 [SMILES: CC1=C(C)C(=O)N(CCCCC2CC3C=CC2C3)C1=O]
1-(4-(bicyclo[2.2.1]hept-5-en-2-yl)butyl)-3,4-dimethyl-1H-pyrrole-2,5-dione (DMMIBuNB); 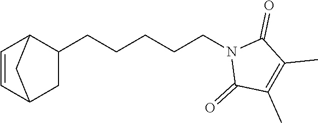 [SMILES: CC1=C(C)C(=O)N(CCCCCC2CC3C=CC2C3)C1=O]
1-(5-(bicyclo[2.2.1]hept-5-en-2-yl)pentyl)-3,4-dimethyl-1H-pyrrole-2,5-dione (DMMIPeNB); 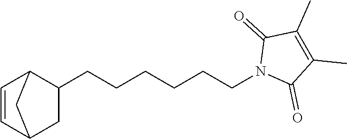 [SMILES: CC1=C(C)C(=O)N(CCCCCCC2CC3C=CC2C3)C1=O]
1-(6-(bicyclo[2.2.1]hept-5-en-2-yl)hexyl)-3,4-dimethyl-1H-pyrrole-2,5-dione (DMMIHxNB); 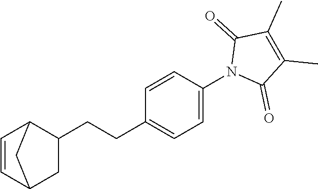 [SMILES: CC1=C(C)C(=O)N(c2ccc(CCC3CC4C=CC3C4)cc2)C1=O]
1-(4-(2-(bicyclo[2.2.1]hept-5-en-2-yl)ethyl)phenyl)-3,4-dimethyl-1H-pyrrole-2,5-dione (DMMIPhEtNB); 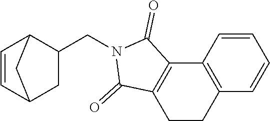 [SMILES: O=C1C2=C(C(=O)N1CC1CC3C=CC1C3)c1ccccc1CC2]
2-(bicyclo[2.2.1]hept-5-en-2-ylmethyl)-4,5-dihydro-1H-benzo[e]isoindole-1,3(2H)-dione (DHNMIMeNB); and 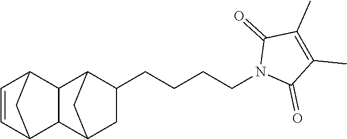 [SMILES: CC1=C(C)C(=O)N(CCCCC2CC3CC2C2C4C=CC(C4)C32)C1=O]
3,4-dimethyl-1-(4-(1,2,3,4,4a,5,8,8a-octahydro-1,4:5,8-dimethanonaphthalen-2-yl)butyl)-1H-pyrrole-2,5-dione (DMMIBuTD).

5. The composition according to claim 1, wherein said compound of formula (III) is selected from the group consisting of: 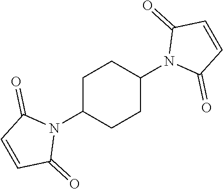 [SMILES: O=C1C=CC(=O)N1C1CCC(N2C(=O)C=CC2=O)CC1]
1,1′-(cyclohexane-1,4-diyl)bis(1H-pyrrole-2,5-dione) (1,4-CyHx(MI)₂); 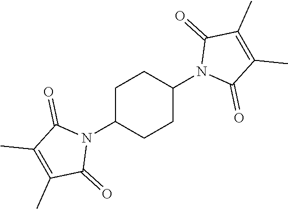
1,1′-(cyclohexane-1,4-diyl)bis(3,4-dimethyl-1H-pyrrole-2,5-dione) (CyHx(DMMI)₂); 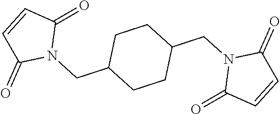 [SMILES: O=C1C=CC(=O)N1CC1CCC(CN2C(=O)C=CC2=O)CC1]
1,1′-(cyclohexane-1,4-diylbis(methylene))bis(1H-pyrrole-2,5-dione) (1,4-CyHxCH₂-MI₂); 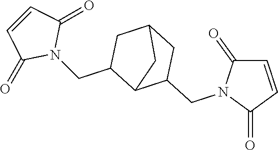 [SMILES: O=C1C=CC(=O)N1CC1CC2CC(CN3C(=O)C=CC3=O)C1C2]
1,1′-(bicyclo[2.2.1]heptane-2,6-diylbis(methylene))bis(1H-pyrrole-2,5-dione) (2,6-NB(CH₂-MI)₂); 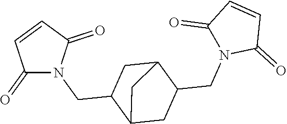 [SMILES: O=C1C=CC(=O)N1CC1CC2CC1CC2CN1C(=O)C=CC1=O]
1,1′-(bicyclo[2.2.1]heptane-2,5-diylbis(methylene))bis(1H-pyrrole-2,5-dione) (2,5-NB(CH₂-MI)₂); 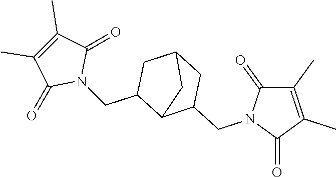
1,1′-(bicyclo[2.2.1]heptane-2,6-diylbis(methylene))bis(3,4-dimethyl-1H-pyrrole-2,5-dione) (2,6-NB(CH₂-DMMI)₂); 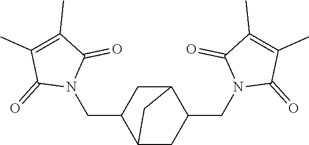
1,1′-(bicyclo[2.2.1]heptane-2,5-diylbis(methylene))bis(3,4-dimethyl-1H-pyrrole-2,5-dione) (2,5-NB(CH₂-DMMI)₂); 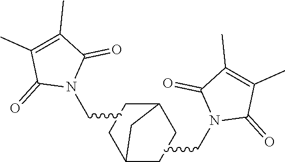
an isomeric mixture of (bicyclo[2.2.1]heptane-diylbis(methylene))bis(3,4-dimethyl-1H-pyrrole-2,5-dione) (NB(CH₂-DMMI)₂); 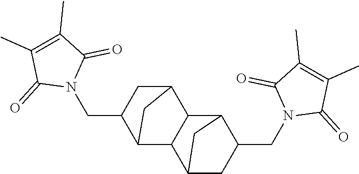
1,1′-((decahydro-1,4:5,8-dimethanonaphthalene-2,6-diyl)bis(methylene))bis(3,4-dimethyl-1H-pyrrole-2,5-dione) (2,6-TD(CH₂-DMMI)₂); 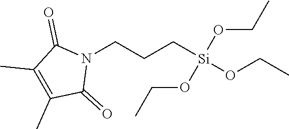 [SMILES: CCO[Si](CCCN1C(=O)C(C)=C(C)C1=O)(OCC)OCC]
3,4-dimethyl-1-[3-(triethoxysilyl)propyl]-1H-pyrrole-2,5-dione (DMMI-Pr-TEOS); 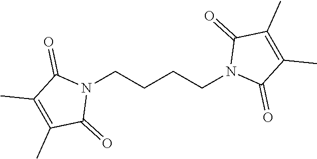
1,1′-(butane-1,4-diyl)bis(3,4-dimethyl-1H-pyrrole-2,5-dione) (DMMI-Bu-DMMI); and 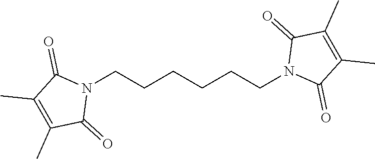
1,1′-(hexane-1,6-diyl)bis(3,4-dimethyl-1H-pyrrole-2,5-dione) (DMMI-Hx-DMMI).

6. The composition according to claim 2, wherein said second repeat unit of formula (IVA) is derived from a monomer of formula (IV) selected from the group consisting of: 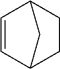
bicyclo[2.2.1]hept-2-ene (norbornene or NB); 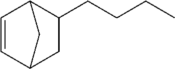
5-butylbicyclo[2.2.1]hept-2-ene (BuNB); 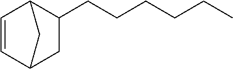
5-hexylbicyclo[2.2.1]hept-2-ene (HexNB); 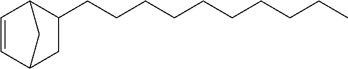 [SMILES: CCCCCCCCCCC1CC2C=CC1C2]
5-decylbicyclo[2.2.1]hept-2-ene (DecNB); 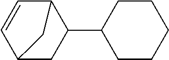 [SMILES: C1=CC2CC1CC2C1CCCCC1]
5-cyclohexylbicyclo[2.2.1]hept-2-ene (CyHexaneNB); 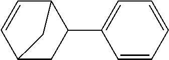 [SMILES: C1=CC2CC1CC2c1ccccc1]
5-phenylbicyclo[2.2.1]hept-2-ene (PhNB); 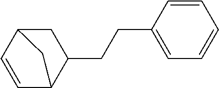 [SMILES: C1=CC2CC1CC2CCc1ccccc1]
5-phenethylbicyclo[2.2.1]hept-2-ene (PENB); 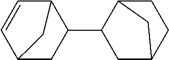 [SMILES: C1=CC2CC1CC2C1CC2CCC1C2]
2,2′-bi(bicyclo[2.2.1]heptan-5-ene) (NBANB); 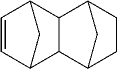 [SMILES: C1=CC2CC1C1C3CCC(C3)C21]
1,2,3,4,4a,5,8,8a-octahydro-1,4:5,8-dimethanonaphthalene (TD); and 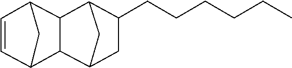 [SMILES: CCCCCCC1CC2CC1C1C3C=CC(C3)C21]
2-hexyl-1,2,3,4,4a,5,8,8a-octahydro-1,4:5,8-dimethanonaphthalene (HexTD).

7. The composition according to claim 1, which is a solution containing a homopolymer of 1-(4-(bicyclo[2.2.1]hept-5-en-2-yl)butyl)-3,4-dimethyl-1H-pyrrole-2,5-dione (DMMIBuNB) and 3,4-dimethyl-1-[3-(triethoxysilyl)propyl]-1H-pyrrole-2,5-dione (DMMI-Pr-TEOS).

8. A patterned layer formed from the composition of claim 1.

9. A patterned layer formed from the composition of claim 2.

10. A microfluidic device comprising a plurality of patterned layers formed from the composition of claim 1.

11. A microfluidic device comprising a plurality of patterned layers formed from the composition of claim 2.

12. A kit for forming a plurality of patterned film layers comprising:
a) a polycycloolefinic polymer comprising at least one first repeat unit of formula (IA),
said first repeat unit is derived from a monomer of formula (I): 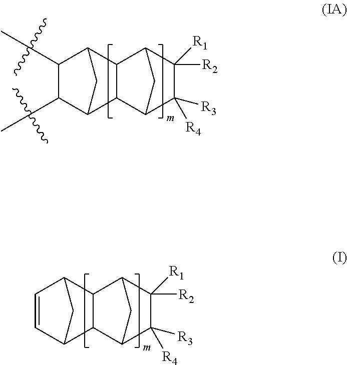
wherein: [symbol]
denotes a place of bonding with another repeat unit;
m is 0, 1 or 2;
at least one of R₁, R₂, R₃ and R₄ is selected from the group consisting of:
a radical of formula (IIA): 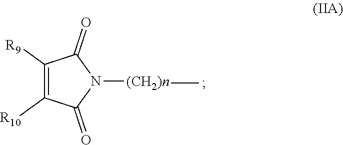
a radical of formula (IIB): 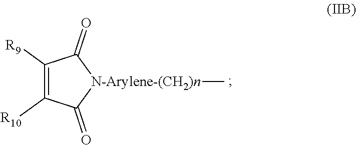
and
a radical of formula (IIC): 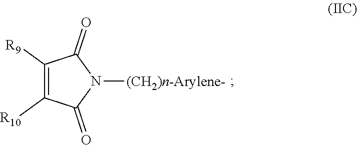
wherein:
n is an integer from 0 to 10, inclusive; and
R₉ and R₁₀ are the same or different and each independently selected from the group consisting of hydrogen, methyl, ethyl and linear or branched (C₃-C₆)alkyl; or
R₉ taken together with R₁₀ and the carbon atoms to which they are attached to form a substituted or unsubstituted (C₃-C₁₄)cyclic, (C₅-C₁₄)bicyclic or (C₅-C₁₄)tricyclic ring optionally containing one or more double bonds;
the remaining R₁, R₂, R₃ and R₄ are the same or different and each independently selected from the group consisting of hydrogen, methyl, ethyl, linear or branched (C₃-C₁₆)alkyl, (C₃-C₁₀)cycloalkyl, (C₆-C₁₂)bicycloalkyl, (C₆-C₁₂)aryl and (C₆-C₁₂)aryl(C₁-C₆)alkyl; or
one of R₁ and R₂ taken together with one of R₃ and R₄ and the carbon atoms to which they are attached to form a substituted or unsubstituted (C₃-C₁₄)cyclic, (C₅-C₁₄)bicyclic or (C₅-C₁₄)tricyclic ring optionally containing one or more double bonds; and
b) a compound of formula (III):
Y—(B)_{q} (III)
wherein,
q is an integer from 1 to 6;
B is a radical of formula (IV): 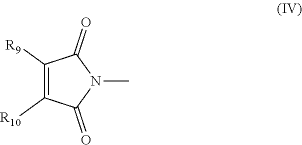
wherein R₉ and R₁₀ are as defined above;
Y is selected from the group consisting of substituted or unsubstituted methyl, ethyl, (C₃-C₁₆)alkyl, substituted or unsubstituted (C₃-C₁₆)cycloalkyl, substituted or unsubstituted (C₃-C₁₆)cycloalkyl(C₁-C₆)alkyl, substituted or unsubstituted (C₆-C₁₆)bicycloalkyl, substituted or unsubstituted (C₆-C₁₆)bicycloalkyl(C₁-C₆)alkyl, substituted or unsubstituted (C₅-C₁₆)tricycloalkyl, substituted or unsubstituted (C₅-C₁₆)tricycloalkyl(C₁-C₆)alkyl, substituted or unsubstituted (C₆-C₁₀)aryl, substituted or unsubstituted (C₆-C₁₀)aryl(C₁-C₁₆)alkyl, substituted or unsubstituted (C₅-C₁₀)heteroaryl and substituted or unsubstituted (C₆-C₁₀)heteroaryl(C₁-C₁₆)alkyl, wherein the substituents are selected from the group consisting of halogen, methoxy, ethoxy, (C₃-C₁₆)alkoxy and tris-(C₁-C₁₆)alkoxysilyl.

13. The kit according to claim 12, wherein the polymer further comprising at least one second repeat unit of formula (IVA), said second repeat unit is derived from a monomer of formula (IV): 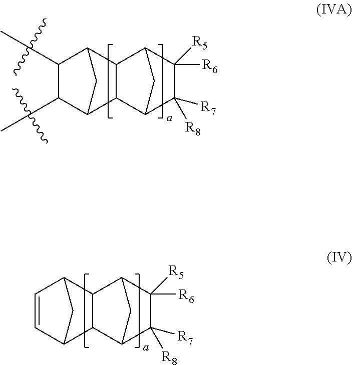
wherein: [symbol]
denotes a place of bonding with another repeat unit;
a is an integer 0, 1 or 2;
R₅, R₆, R₇ and R₈ are the same or different and each independently selected from the group consisting of hydrogen, halogen, methyl, ethyl, linear or branched (C₃-C₁₆)alkyl, (C₃-C₁₀)cycloalkyl, (C₆-C₁₂)bicycloalkyl, (C₆-C₁₂)aryl and (C₆-C₁₂)aryl(C₁-C₆)alkyl, methoxy, ethoxy, linear or branched (C₃-C₁₆)alkoxy, (C₃-C₁₂)cycloalkoxy, (C₆-C₁₂)bicycloalkoxy, (C₇-C₁₄)tricycloalkoxy, (C₆-C₁₀)aryloxy and (C₆-C₁₀)aryl(C₁-C₆)alkoxy; or
one of R₅ and R₆ taken together with one of R₇ and R₈ and the carbon atoms to which they are attached to form a substituted or unsubstituted (C₅-C₁₄)cyclic, (C₅-C₁₄)bicyclic or (C₅-C₁₄)tricyclic ring optionally containing one or more double bonds.

14. The kit according to claim 12, which contains a solution of a homopolymer of 1-(4-(bicyclo[2.2.1]hept-5-en-2-yl)butyl)-3,4-dimethyl-1H-pyrrole-2,5-dione (DMMIBuNB) and 3,4-dimethyl-1-[3-(triethoxysilyl)propyl]-1H-pyrrole-2,5-dione (DMMI-Pr-TEOS).

15. A method of forming a patterned layers comprising:
a) coating a substrate with a composition, said composition comprising:
i) a polycycloolefinic polymer comprising at least one first repeat unit of formula (IA), said first repeat unit is derived from a monomer of formula (I): 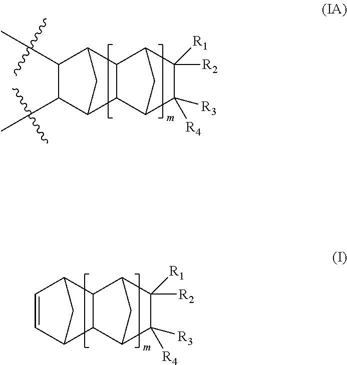
wherein: [symbol]
denotes a place of bonding with another repeat unit;
m is 0, 1 or 2;
at least one of R₁, R₂, R₃ and R₄ is selected from the group consisting of:
a radical of formula (IIA): 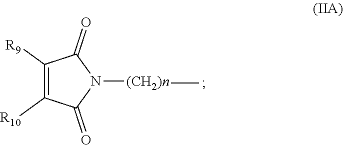
a radical of formula (IIB): 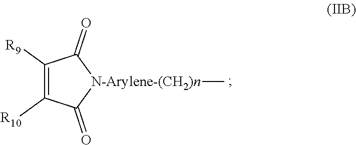
and
a radical of formula (IIC): 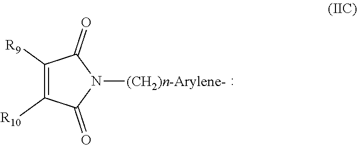
wherein:
n is an integer from 0 to 10, inclusive; and
R₉ and R₁₀ are the same or different and each independently selected from the group consisting of hydrogen, methyl, ethyl and linear or branched (C₃-C₆)alkyl; or
R₉ taken together with R₁₀ and the carbon atoms to which they are attached to form a substituted or unsubstituted (C₃-C₁₄)cyclic, (C₅-C₁₄)bicyclic or (C₅-C₁₄)tricyclic ring optionally containing one or more double bonds;
the remaining R₁, R₂, R₃ and R₄ are the same or different and each independently selected from the group consisting of hydrogen, methyl, ethyl, linear or branched (C₃-C₁₆)alkyl, (C₃-C₁₀)cycloalkyl, (C₆-C₁₂)bicycloalkyl, (C₆-C₁₂)aryl and (C₆-C₁₂)aryl(C₁-C₆)alkyl; or
one of R₁ and R₂ taken together with one of R₃ and R₄ and the carbon atoms to which they are attached to form a substituted or unsubstituted (C₃-C₁₄)cyclic, (C₅-C₁₄)bicyclic or (C₅-C₁₄)tricyclic ring optionally containing one or more double bonds; and
ii) a compound of formula (III):
Y—(B)_{q} (III)
wherein,
q is an integer from 1 to 6;
B is a radical of formula (IV): 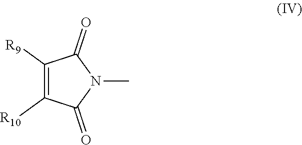
wherein R₉ and R₁₀ are as defined above;
Y is selected from the group consisting of substituted or unsubstituted methyl, ethyl, (C₃-C₁₆)alkyl, substituted or unsubstituted (C₃-C₁₆)cycloalkyl, substituted or unsubstituted (C₃-C₁₆)cycloalkyl(C₁-C₆)alkyl, substituted or unsubstituted (C₆-C₁₆)bicycloalkyl, substituted or unsubstituted (C₆-C₁₆)bicycloalkyl(C₁-C₆)alkyl, substituted or unsubstituted (C₅-C₁₆)tricycloalkyl, substituted or unsubstituted (C₅-C₁₆)tricycloalkyl(C₁-C₆)alkyl, substituted or unsubstituted (C₆-C₁₀)aryl, substituted or unsubstituted (C₆-C₁₀)aryl(C₁-C₁₆)alkyl, substituted or unsubstituted (C₅-C₁₀)heteroaryl and substituted or unsubstituted (C₆-C₁₀)heteroaryl(C₁-C₁₆)alkyl, wherein the substituents are selected from the group consisting of halogen, methoxy, ethoxy, (C₃-C₁₆)alkoxy and tris-(C₁-C₁₆)alkoxysilyl;
b) placing a patterned soft stamp on the coated substrate;
c) placing a glass slide on top of the soft stamp to form a stack;
d) exposing the stack to a suitable actinic radiation;
e) removing the glass slide and the stamp to obtain the patterned substrate.

16. The method according to claim 15, wherein the composition contains a polymer further comprising at least one second repeat unit of formula (IVA), said second repeat unit is derived from a monomer of formula (IV): 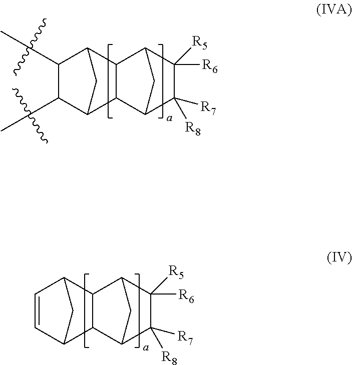
wherein: [symbol]
denotes a place of bonding with another repeat unit;
a is an integer 0, 1 or 2;
R₅, R₆, R₇ and R₈ are the same or different and each independently selected from the group consisting of hydrogen, halogen, methyl, ethyl, linear or branched (C₃-C₁₆)alkyl, (C₃-C₁₀)cycloalkyl, (C₆-C₁₂)bicycloalkyl, (C₆-C₁₂)aryl and (C₆-C₁₂)aryl(C₁-C₆)alkyl, methoxy, ethoxy, linear or branched (C₃-C₁₆)alkoxy, (C₃-C₁₂)cycloalkoxy, (C₆-C₁₂)bicycloalkoxy, (C₇-C₁₄)tricycloalkoxy, (C₆-C₁₀)aryloxy and (C₆-C₁₀)aryl(C₁-C₆)alkoxy; or
one of R₅ and R₆ taken together with one of R₇ and R₈ and the carbon atoms to which they are attached to form a substituted or unsubstituted (C₅-C₁₄)cyclic, (C₅-C₁₄)bicyclic or (C₅-C₁₄)tricyclic ring optionally containing one or more double bonds.

17. The method according to claim 15, wherein said polymer having a first repeat unit of formula (IA) which is derived from a monomer of formula (I) selected from the group consisting of: 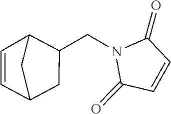
1-(bicyclo[2.2.1]hept-5-en-2-ylmethyl)-1H-pyrrole-2,5-dione (MIMeNB); 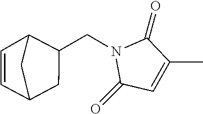 [SMILES: CC1=CC(=O)N(CC2CC3C=CC2C3)C1=O]
1-(bicyclo[2.2.1]hept-5-en-2-ylmethyl)-3-methyl-1H-pyrrole-2,5-dione (MMIMeNB); 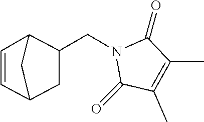 [SMILES: CC1=C(C)C(=O)N(CC2CC3C=CC2C3)C1=O]
1-(bicyclo[2.2.1]hept-5-en-2-ylmethyl)-3,4-dimethyl-1H-pyrrole-2,5-dione (DMMIMeNB); 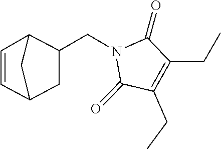 [SMILES: CCC1=C(CC)C(=O)N(CC2CC3C=CC2C3)C1=O]
1-(bicyclo[2.2.1]hept-5-en-2-ylmethyl)-3,4-diethyl-1H-pyrrole-2,5-dione (DEMIMeNB); 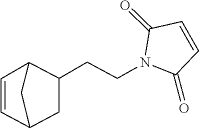 [SMILES: O=C1C=CC(=O)N1CCC1CC2C=CC1C2]
1-(2-(bicyclo[2.2.1]hept-5-en-2-yl)ethyl)-1H-pyrrole-2,5-dione (MIEtNB); 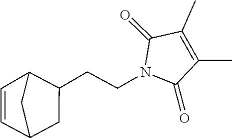 [SMILES: CC1=C(C)C(=O)N(CCC2CC3C=CC2C3)C1=O]
1-(2-(bicyclo[2.2.1]hept-5-en-2-yl)ethyl)-3,4-dimethyl-1H-pyrrole-2,5-dione (DMMIEtNB); 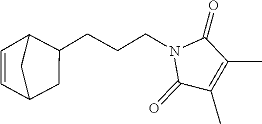 [SMILES: CC1=C(C)C(=O)N(CCCC2CC3C=CC2C3)C1=O]
1-(3-(bicyclo[2.2.1]hept-5-en-2-yl)propyl)-3,4-dimethyl-1H-pyrrole-2,5-dione (DMMIPrNB); 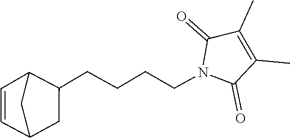 [SMILES: CC1=C(C)C(=O)N(CCCCC2CC3C=CC2C3)C1=O]
1-(4-(bicyclo[2.2.1]hept-5-en-2-yl)butyl)-3,4-dimethyl-1H-pyrrole-2,5-dione (DMMIBuNB); 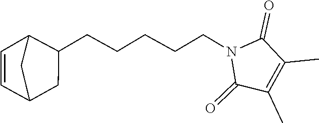 [SMILES: CC1=C(C)C(=O)N(CCCCCC2CC3C=CC2C3)C1=O]
1-(5-(bicyclo[2.2.1]hept-5-en-2-yl)pentyl)-3,4-dimethyl-1H-pyrrole-2,5-dione (DMMIPeNB); 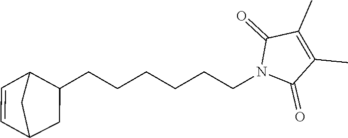 [SMILES: CC1=C(C)C(=O)N(CCCCCCC2CC3C=CC2C3)C1=O]
1-(6-(bicyclo[2.2.1]hept-5-en-2-yl)hexyl)-3,4-dimethyl-1H-pyrrole-2,5-dione (DMMIHxNB); 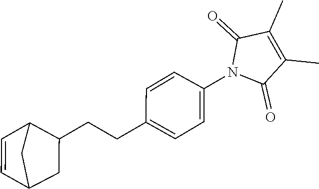 [SMILES: CC1=C(C)C(=O)N(c2ccc(CCC3CC4C=CC3C4)cc2)C1=O]
1-(4-(2-(bicyclo[2.2.1]hept-5-en-2-yl)ethyl)phenyl)-3,4-dimethyl-1H-pyrrole-2,5-dione (DMMIPhEtNB); and 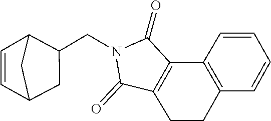 [SMILES: O=C1C2=C(C(=O)N1CC1CC3C=CC1C3)c1ccccc1CC2]
2-(bicyclo[2.2.1]hept-5-en-2-ylmethyl)-4,5-dihydro-1H-benzo[e]isoindole-1,3(2H)-dione (DHNMIMeNB).

18. The method according to claim 15, wherein said compound of formula (III) is selected from the group consisting of: 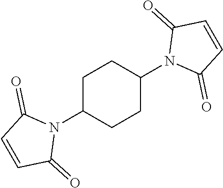 [SMILES: O=C1C=CC(=O)N1C1CCC(N2C(=O)C=CC2=O)CC1]
1,1′-(cyclohexane-1,4-diyl)bis(1H-pyrrole-2,5-dione) (1,4-CyHx(MI)₂); 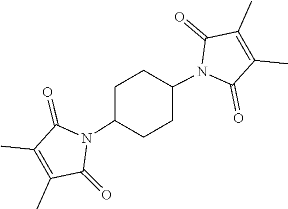
1,1′-(cyclohexane-1,4-diyl)bis(3,4-dimethyl-1H-pyrrole-2,5-dione) (CyHx(DMMI)₂); 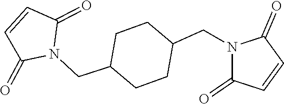 [SMILES: O=C1C=CC(=O)N1CC1CCC(CN2C(=O)C=CC2=O)CC1]
1,1′-(cyclohexane-1,4-diylbis(methylene))bis(1H-pyrrole-2,5-dione) (1,4-CyHxCH₂-MI₂); 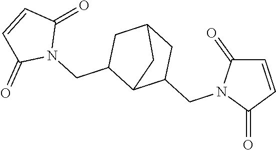 [SMILES: O=C1C=CC(=O)N1CC1CC2CC(CN3C(=O)C=CC3=O)C1C2]
1,1′-(bicyclo[2.2.1]heptane-2,6-diylbis(methylene))bis(1H-pyrrole-2,5-dione) (2,6-NB(CH₂-MI)₂); 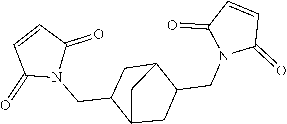 [SMILES: O=C1C=CC(=O)N1CC1CC2CC1CC2CN1C(=O)C=CC1=O]
1,1′-(bicyclo[2.2.1]heptane-2,5-diylbis(methylene))bis(1H-pyrrole-2,5-dione) (2,5-NB(CH₂-MI)₂); 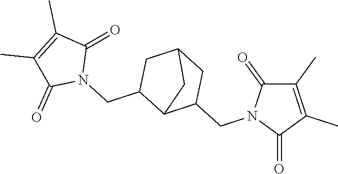
1,1′-(bicyclo[2.2.1]heptane-2,6-diylbis(methylene))bis(3,4-dimethyl-1H-pyrrole-2,5-dione) (2,6-NB(CH₂-DMMI)₂); 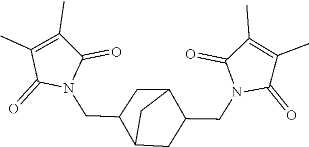
1,1′-(bicyclo[2.2.1]heptane-2,5-diylbis(methylene))bis(3,4-dimethyl-1H-pyrrole-2,5-dione) (2,5-NB(CH₂-DMMI)₂); 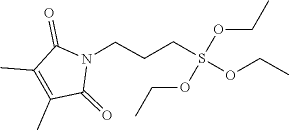 [SMILES: CCOS(CCCN1C(=O)C(C)=C(C)C1=O)(OCC)OCC]
3,4-dimethyl-1-[3-(triethoxysilyl)propyl]-1H-pyrrole-2,5-dione (DMMI-Pr-TEOS); 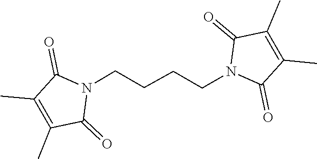
1,1′-(butane-1,4-diyl)bis(3,4-dimethyl-1H-pyrrole-2,5-dione) (DMMI-Bu-DMMI); and 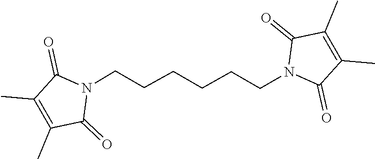
1,1′-(hexane-1,6-diyl)bis(3,4-dimethyl-1H-pyrrole-2,5-dione) (DMMI-Hx-DMMI).

19. The method according to claim 16, wherein said polymer having a second repeat unit of formula (IVA) which is derived from a monomer of formula (IV) selected from the group consisting of: 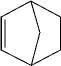
bicyclo[2.2.1]hept-2-ene (norbornene or NB); 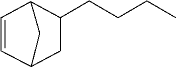
5-butylbicyclo[2.2.1]hept-2-ene (BuNB); 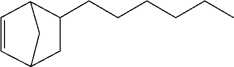
5-hexylbicyclo[2.2.1]hept-2-ene (HexNB); 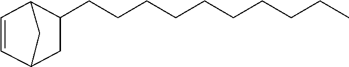 [SMILES: CCCCCCCCCCC1CC2C=CC1C2]
5-decylbicyclo[2.2.1]hept-2-ene (DecNB); 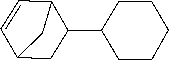 [SMILES: C1=CC2CC1CC2C1CCCCC1]
5-cyclohexylbicyclo[2.2.1]hept-2-ene (CyHexaneNB); 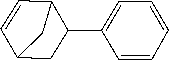 [SMILES: C1=CC2CC1CC2c1ccccc1]
5-phenylbicyclo[2.2.1]hept-2-ene (PhNB); 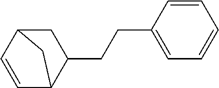 [SMILES: C1=CC2CC1CC2CCc1ccccc1]
5-phenethylbicyclo[2.2.1]hept-2-ene (PENB); 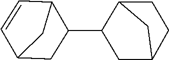 [SMILES: C1=CC2CC1CC2C1CC2CCC1C2]
2,2′-bi(bicyclo[2.2.1]heptan-5-ene) (NBANB); 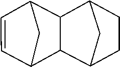 [SMILES: C1=CC2CC1C1C3CCC(C3)C21]
1,2,3,4,4a,5,8,8a-octahydro-1,4:5,8-dimethanonaphthalene (TD); and 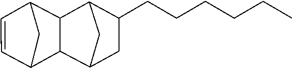 [SMILES: CCCCCCC1CC2CC1C1C3C=CC(C3)C21]
2-hexyl-1,2,3,4,4a,5,8,8a-octahydro-1,4:5,8-dimethanonaphthalene (HexTD).

20. The method according to claim 15, wherein said composition is a solution containing a homopolymer of 1-(4-(bicyclo[2.2.1]hept-5-en-2-yl)butyl)-3,4-dimethyl-1H-pyrrole-2,5-dione (DMMIBuNB) and 3,4-dimethyl-1-[3-(triethoxysilyl)propyl]-1H-pyrrole-2,5-dione (DMMI-Pr-TEOS).
